(19) United States
(12) Patent Application Publication
(10) Pub. No.: US 2024/0405110 A1
(43) Pub. Date: Dec. 5, 2024

(54) SEMICONDUCTOR DEVICE

(71) Applicant: ROHM CO., LTD., Kyoto-shi (JP)

(72) Inventor: Takayuki OSAWA, Kyoto-shi (JP)

(73) Assignee: ROHM CO., LTD., Kyoto-shi (JP)

(21) Appl. No.: 18/806,730

(22) Filed: Aug. 16, 2024

Related U.S. Application Data
(63) Continuation of application No. PCT/JP2022/043909, filed on Nov. 29, 2022.

(30) Foreign Application Priority Data
Feb. 18, 2022 (JP) 2022-024185

(51) Int. Cl. H01L 29/739; H01L 29/06; H01L 29/66

(52) U.S. Cl. CPC H01L 29/7397; H01L 29/0611; H01L 29/66348

(57) ABSTRACT

A semiconductor device includes a chip with a main surface, featuring a first conductivity type base region. A trench gate structure penetrates the base region, while a second conductivity type emitter region is formed along the trench gate structure on the surface. Between the bottom of the base region and the emitter region, a higher impurity concentration in-base region is present. An insulating film covers the main surface, featuring a connection hole that exposes part of the emitter region at a distance from the in-base region. A connection electrode is positioned in the connection hole, electrically connecting the base and emitter regions.

### CROSS-REFERENCE TO RELATED APPLICATIONS

The present application is a bypass continuation of International Patent Application No. PCT/JP2022/043909, filed on Nov. 29, 2022, which claims priority to Japanese Patent Application No. 2022-024185 filed in the Japan Patent Office on Feb. 18, 2022, and the entire disclosure of these applications are incorporated herein by reference.

### BACKGROUND

### 1. Field of the Disclosure

The present disclosure relates to a semiconductor device.

### 2. Description of the Related Art

US20180069110A1 discloses a semiconductor device that includes a semiconductor substrate, a p-type body region, a trench gate structure, an n-type emitter region, an insulating film, a p-type contact region, and an emitter electrode. The semiconductor substrate has a main surface. The body region is formed in a surficial portion of the main surface. The trench gate structure is formed in the main surface so as to penetrate the body region. The emitter region is formed in the body region so as to be contiguous to the trench gate structure.

The insulating film covers the main surface, and has a contact groove that exposes the emitter region. The contact region is formed in the body region so as to be exposed from the contact groove. The emitter electrode is electrically connected to the emitter region and to the contact region in the contact groove.

### BRIEF DESCRIPTION OF THE DRAWINGS

FIG. 1 is a plan view showing a semiconductor device according to a first embodiment.

FIG. 2 is an enlarged view of region II shown in FIG. 1.

FIG. 3 is a cross-sectional view along line III-III shown in FIG. 2.

FIG. 4 is a cross-sectional view along line IV-IV shown in FIG. 2.

FIG. 5 is a cross-sectional view along line V-V shown in FIG. 2.

FIG. 6 is a cross-sectional view along line VI-VI shown in FIG. 2.

FIG. 7 is a cross-sectional view along line VII-VII shown in FIG. 2.

FIG. 8 is a cross-sectional perspective view showing a main portion of the semiconductor device shown in FIG. 1.

FIG. 9 is a cross-sectional perspective view in which an emitter electrode has been removed from FIG. 8.

FIG. 10 is a cross-sectional perspective view in which an interlayer insulating film has been removed from FIG. 9.

FIG. 11 is a cross-sectional view of semiconductor device according to a reference example, which is shown together with resistance symbols.

FIG. 12 is a cross-sectional view of the semiconductor device according to the embodiment, which is shown together with resistance symbols.

FIGS. 13A to 13R are cross-sectional perspective views showing an example of a manufacturing method of the semiconductor device shown in FIG. 1.

FIG. 14 is a cross-sectional view showing a semiconductor device according to a second embodiment.

FIG. 15 is a cross-sectional view showing a semiconductor device according to a third embodiment.

FIG. 16 is a cross-sectional view showing a semiconductor device according to a fourth embodiment.

FIG. 17 is a cross-sectional view showing a semiconductor device according to a fifth embodiment.

FIG. 18 is a cross-sectional view showing a semiconductor device according to a sixth embodiment.

FIG. 19 is a cross-sectional view showing a semiconductor device according to a seventh embodiment.

FIG. 20 is a cross-sectional view showing a semiconductor device according to an eighth embodiment.

FIG. 21 is a cross-sectional view showing a semiconductor device according to a ninth embodiment.

FIG. 22 is a plan view showing a main portion of a semiconductor device according to a tenth embodiment.

FIG. 23 is a cross-sectional view along line XXIII-XXIII shown in FIG. 22.

FIG. 24 is a cross-sectional view along line XXIV-XXIV shown in FIG. 22.

### DETAILED DESCRIPTION OF THE PREFERRED EMBODIMENTS

Embodiments will be hereinafter described in detail with reference to the accompanying drawings. The accompanying drawings are schematic views, and are not strictly shown, and do not necessarily coincide with each other in scale and the like. Also, the same reference sign is assigned to a constituent that corresponds to each constituent in the accompanying drawings, and a duplicated description of this constituent is omitted or simplified. A description of a constituent, which has not yet been omitted or simplified, is applied to a corresponding constituent a description of which has been omitted or simplified.

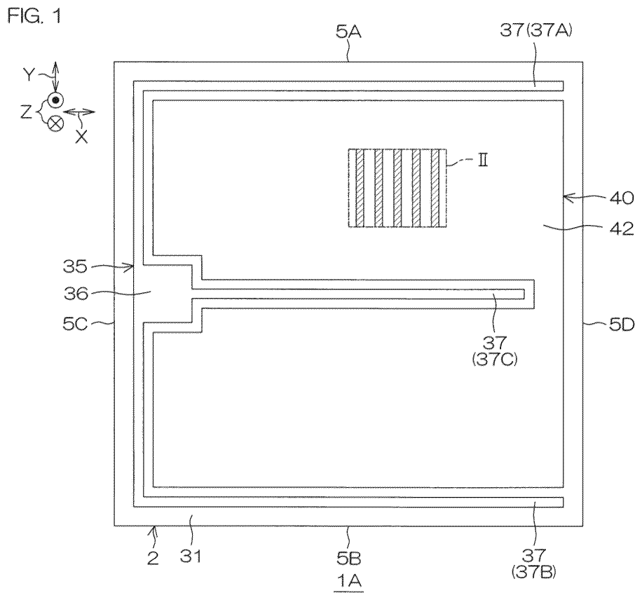

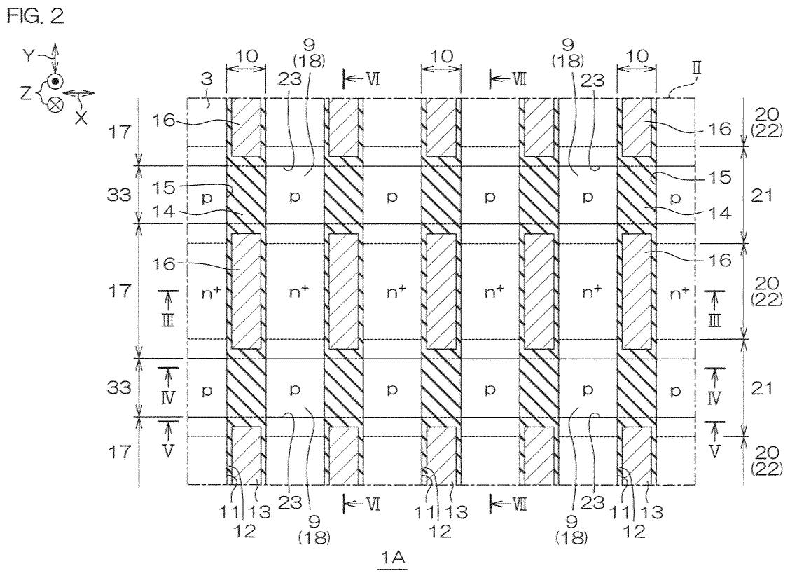

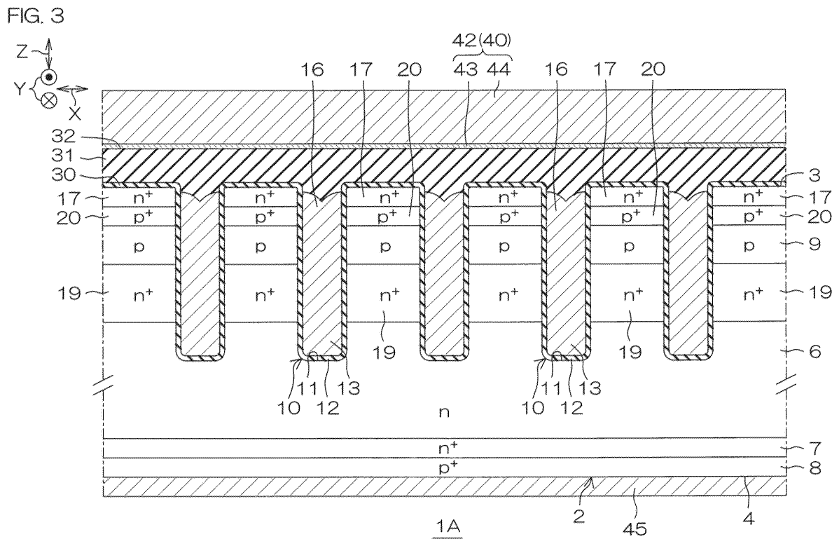

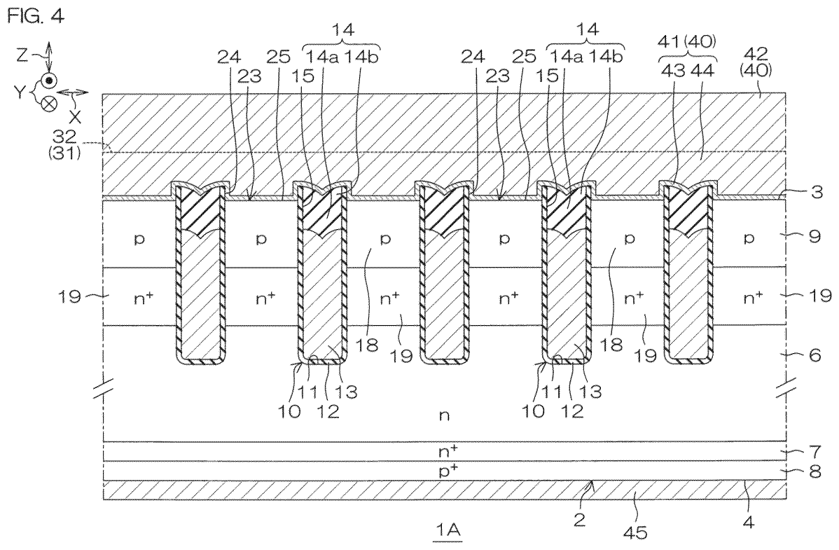

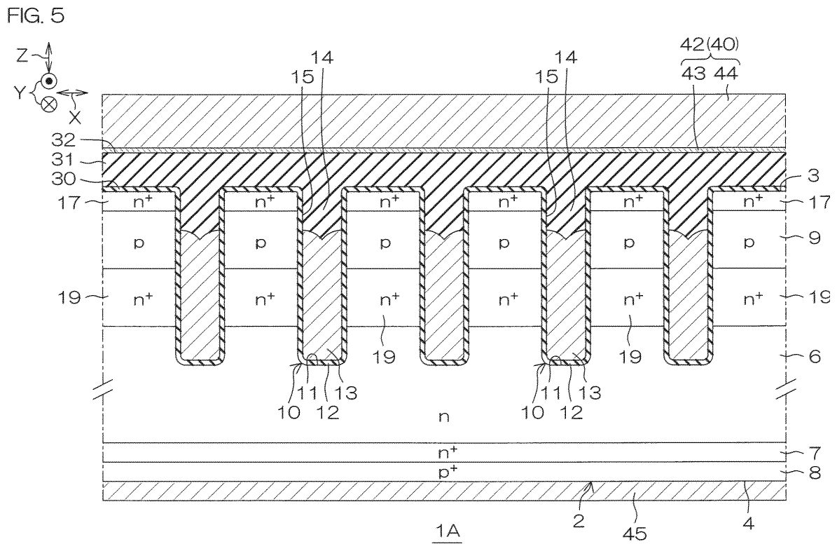

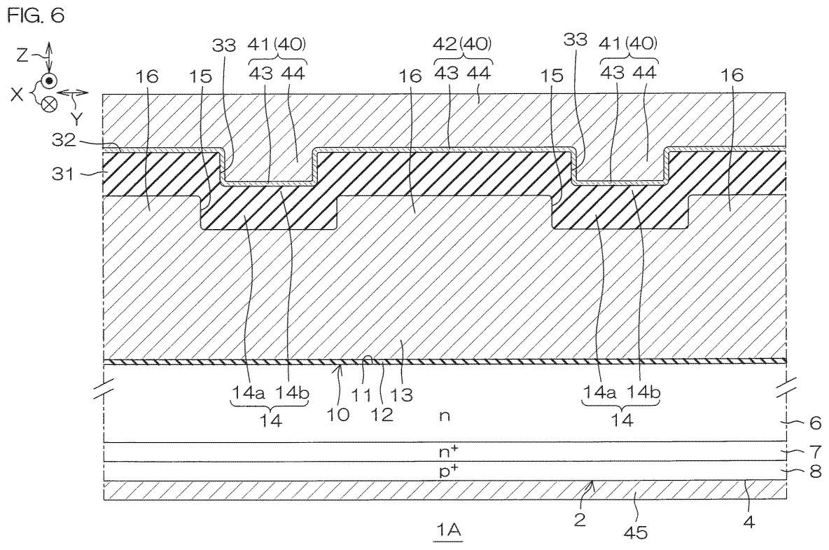

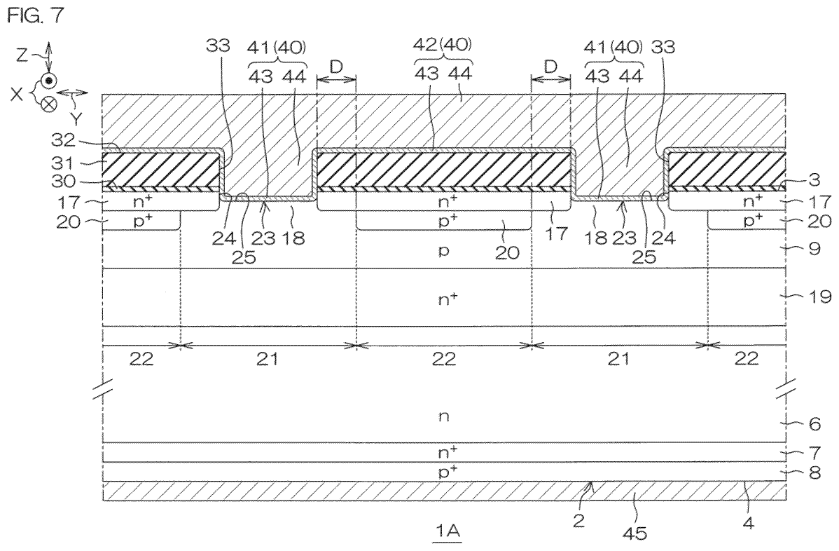

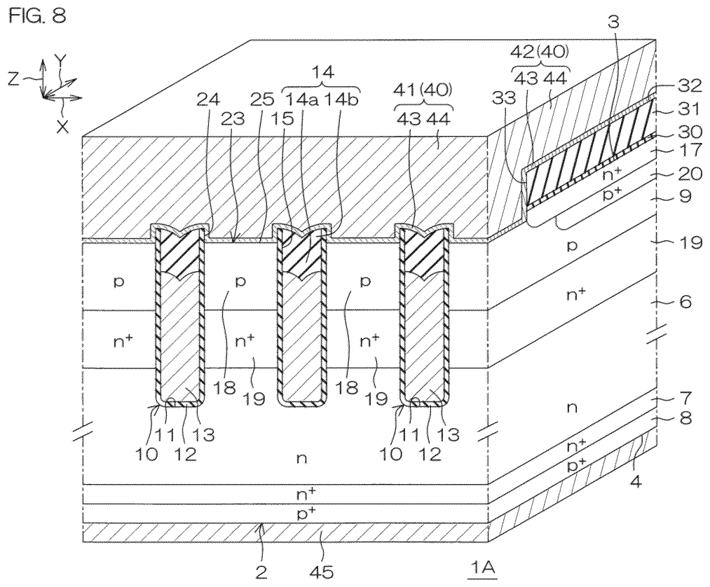

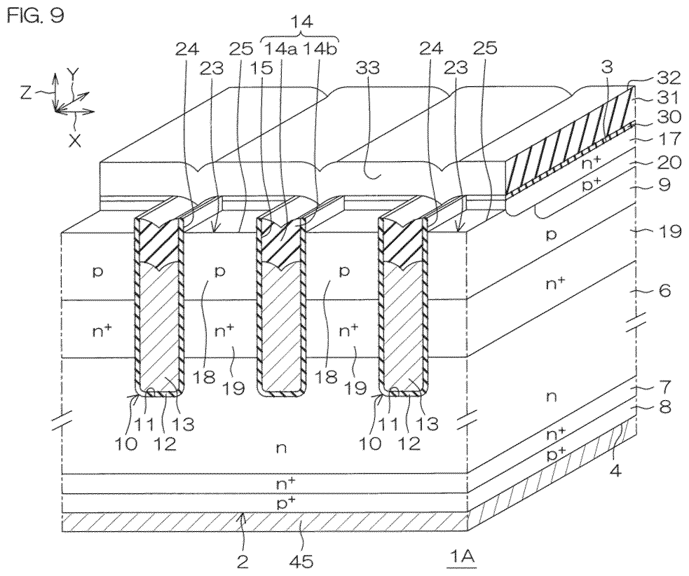

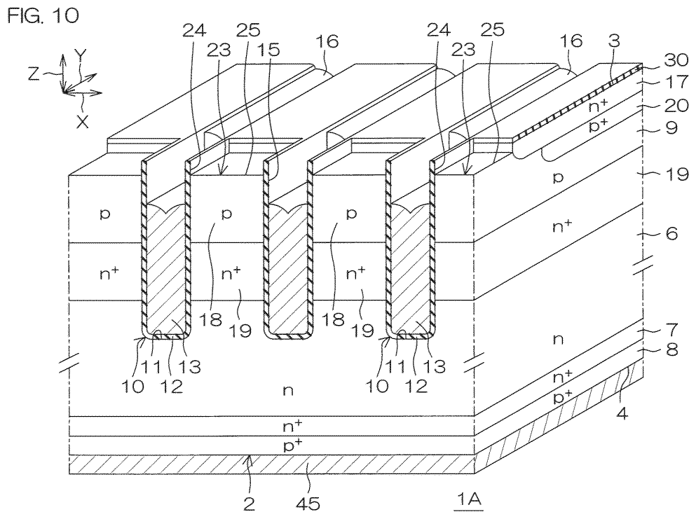

FIG. 1 is a plan view showing a semiconductor device 1A according to a first embodiment. FIG. 2 is an enlarged view of region II shown in FIG. 1. FIG. 3 is a cross-sectional view along line III-III shown in FIG. 2. FIG. 4 is a cross-sectional view along line IV-IV shown in FIG. 2. FIG. 5 is a cross-sectional view along line V-V shown in FIG. 2. FIG. 6 is a cross-sectional view along line VI-VI shown in FIG. 2. FIG. 7 is a cross-sectional view along line VII-VII shown in FIG. 2. FIG. 8 is a cross-sectional perspective view showing a main portion of the semiconductor device 1A shown in FIG. 1. FIG. 9 is a cross-sectional perspective view in which an emitter electrode 40 has been removed from FIG. 8. FIG. 10 is a cross-sectional perspective view in which an interlayer insulating film 31 has been removed from FIG. 9.

Referring to FIG. 1 to FIG. 10, the semiconductor device 1A is a semiconductor switching device including an IGBT (Insulated Gate Bipolar Transistor). The semiconductor device 1A includes a chip 2 having a hexahedral shape (specifically, rectangular parallelepiped shape). In this embodiment, the chip 2 has a single-layer structure consisting of a silicon monocrystal substrate (semiconductor substrate). The chip 2 may have a thickness of not less than 50 μm and not more than 400 μm.

The chip 2 has a first main surface 3 on one side, a second main surface 4 on the other side, and first to fourth side surfaces 5A to 5D that connect the first and second main surfaces 3 and 4. The first and second main surfaces 3 and 4 are each formed in a quadrangular shape in a plan view seen from their normal directions Z (hereinafter, referred to simply as a “plan view”). The normal direction Z is also a thickness direction of the chip 2.

The first side surface 5A and the second side surface 5B extend in a first direction X along the first main surface 3, and face a second direction Y that intersects (specifically, perpendicularly intersects) the first direction X. The third side surface 5C and the fourth side surface 5D extend in the second direction Y, and face the first direction X.

The semiconductor device 1A includes an n-type drift region 6 formed inside the chip 2. The drift region 6 is formed in the whole area of the inside of the chip 2. In this embodiment, the chip 2 is made of an n-type semiconductor chip, and the drift region 6 is formed by use of the chip 2.

The semiconductor device 1A includes an n-type buffer region 7 formed in a surficial portion of the second main surface 4. The buffer region 7 extends in a layer shape along the second main surface 4, and is exposed from a part of the first to fourth side surfaces 5A to 5D. The buffer region 7 has an n-type impurity concentration higher than the drift region 6.

The semiconductor device 1A includes a p-type collector region 8 formed in the surficial portion of the second main surface 4. In this embodiment, the collector region 8 is formed in a surficial portion, which is located on the second main surface 4 side, of the buffer region 7. In this embodiment, the collector region 8 is formed in a layer shape extending along the second main surface 4 in the whole area of the second main surface 4. The collector region 8 is exposed from the second main surface 4 and from a part of the first to fourth side surfaces 5A to 5D.

The semiconductor device 1A includes a p-type base region 9 formed in a surficial portion of the first main surface 3. The base region 9 is formed in a layer shape extending along the first main surface 3. The base region 9 is formed at an inward portion of the chip 2 at a distance from a peripheral edge of the chip 2.

The semiconductor device 1A includes a plurality of trench gate structures 10 formed in the first main surface 3. A gate potential is given to the trench gate structure 10. The plurality of trench gate structures 10 penetrate the base region 9 so as to reach the drift region 6. The plurality of trench gate structures 10 are arrayed at a distance from each other in the first direction X in a plan view, and are each formed in a belt shape extending in the second direction Y. That is, the plurality of trench gate structures 10 are arrayed in a stripe shape extending in the second direction Y.

The plurality of trench gate structures 10 may each have a width of not less than 0.5 μm and not more than 3 μm. The plurality of trench gate structures 10 may each have a depth of not less than 1 μm and not more than 10 μm. The distance (trench pitch) between the plurality of trench gate structures 10 may be not less than 0.1 μm and not more than 3.5 μm. Preferably, the distance between the plurality of trench gate structures 10 is 1 μm or less.

A configuration of the single trench gate structure 10 will be hereinafter described. The trench gate structure 10 includes a gate trench 11, a gate insulating film 12, a gate embedded electrode 13, and at least one (in this embodiment, a plurality of) recess insulator 14. The gate trench 11 is dug down from the first main surface 3 toward the second main surface 4, and defines a wall surface of the trench gate structure 10.

The gate trench 11 extends in a direction perpendicular to the first main surface 3. The gate trench 11 may be formed in a tapered shape in which the width of its opening becomes narrower from the opening toward its bottom wall. Preferably, the bottom wall of the gate trench 11 is formed in a curved shape toward the second main surface 4. As a matter of course, the bottom wall of the gate trench 11 may be formed in parallel with the first main surface 3. In this case, preferably, a corner portion of the bottom wall of the gate trench 11 is formed in a curved shape.

The gate insulating film 12 covers the wall surface of the gate trench 11 as a film, and defines a recessed space in the gate trench 11. The gate insulating film 12 may include at least one among a silicon oxide film, a silicon nitride film, a silicon oxynitride film, and an aluminum oxide film. Preferably, the gate insulating film 12 includes a silicon oxide film made of an oxide of the chip 2.

The gate embedded electrode 13 is embedded in the gate trench 11 with the gate insulating film 12 between the gate embedded electrode 13 and the gate trench 11. The gate potential is given to the gate embedded electrode 13. The gate embedded electrode 13 may include conductive polysilicon. The gate embedded electrode 13 faces the drift region 6 and the base region 9 across the gate insulating film 12. The gate embedded electrode 13 may have an upper end portion placed on the bottom wall side of the gate trench 11 with respect to the first main surface 3.

The gate embedded electrode 13 has an uneven structure that is upheaved toward the opening side and the bottom wall side of the gate trench 11 along an extending direction of the gate trench 11 (i.e., along the second direction Y) in an electrode surface (upper end portion). Specifically, the gate embedded electrode 13 has at least one (in this embodiment, a plurality of) electrode recess portion 15 and at least one (in this embodiment, a plurality of) electrode projection portion 16 in the upper end portion.

The plurality of electrode recess portions 15 are hollowed from an electrode surface of the gate trench 11 toward the bottom wall of the gate trench 11, and are formed at a distance in the extending direction of the trench gate structure 10. In this embodiment, the plurality of electrode recess portions 15 are each formed in a belt shape extending in the extending direction of the trench gate structure 10 in a plan view.

That is, each of the electrode recess portions 15 has a layout in which the length in the second direction Y is larger than the length in the first direction X in a plan view. The length of each of the electrode recess portions 15 may be not less than 0.5 μm and not more than 10 μm. Preferably, the length of each of the electrode projection portions 16 is 7 μm or less. Particularly preferably, the length of each of the electrode projection portions 16 is 5 μm or less.

The plurality of electrode recess portions 15 each have a bottom portion located closer to the first main surface 3 side than an intermediate portion in a depth range of the gate trench 11. Specifically, the bottom portion of the plurality of electrode recess portions 15 is located closer to the first main surface 3 side than a bottom portion of the base region 9. That is, the plurality of electrode recess portions 15 face the base region 9 in a surface direction (first direction X) of the first main surface 3. The bottom portion of each of the electrode recess portions 15 may have a hollow toward the bottom wall side of the gate trench 11.

The plurality of electrode projection portions 16 are defined between the plurality of electrode recess portions 15 adjoining each other, and protrude from the plurality of electrode recess portions 15 toward the opening end side of the gate trench 11. That is, the plurality of electrode projection portions 16 face the base region 9 across the gate insulating film 12. In this embodiment, the plurality of electrode projection portions 16 are each formed in a belt shape extending in the extending direction of the trench gate structure 10 in a plan view. That is, each of the electrode projection portions 16 has a layout in which the length in the second direction Y is larger than the length in the first direction X in a plan view.

Preferably, the length of each of the electrode projection portions 16 is equal to or more than the length of each of the electrode recess portions 15, and, particularly preferably, is more than the length of each of the electrode recess portions 15. The length of each of the electrode projection portions 16 may be not less than 1 μm and not more than 10 μm. Preferably, the length of each of the electrode projection portions 16 is 5 μm or less. Particularly preferably, the length of each of the electrode projection portions 16 is 3 μm or less. As a matter of course, the length of each of the electrode projection portions 16 may be less than length of each of the electrode recess portions 15.

With respect to a plurality of pairs of trench gate structures 10 adjoining each other, the plurality of electrode recess portions 15 according to one of the trench gate structures 10 face the plurality of electrode recess portions 15 according to the other trench gate structure 10 in the first direction X. That is, the plurality of electrode recess portions 15 are formed in a matrix manner at a distance from each other in the first and second directions X and Y.

As a matter of course, the plurality of electrode recess portions 15 according to one of the trench gate structures 10 may face the plurality of electrode projection portions 16 according to the other trench gate structure 10 in the first direction X. That is, the plurality of electrode recess portions 15 may be formed in a staggered manner at a distance from each other in the first and second directions X and Y.

The plurality of recess insulators 14 are embedded in the plurality of electrode recess portions 15, respectively. The plurality of recess insulators 14 may include at least one among silicon oxide, silicon nitride, silicon oxynitride, and aluminum oxide. Preferably, the plurality of recess insulators 14 include the same insulation material as the gate insulating film 12. Preferably, the plurality of recess insulators 14 include silicon oxide.

Each of the recess insulators 14 has a planar shape and a sectional shape that coincide with a planar shape and a sectional shape of each of the electrode recess portions 15. In this embodiment, the plurality of recess insulators 14 are each embedded in a belt shape extending in the extending direction of the trench gate structure 10. The plurality of recess insulators 14 face each other across the electrode projection portion 16 in the extending direction of the trench gate structure 10. The plurality of recess insulators 14 each have a portion contiguous to the base region 9. In other words, a part, which is formed by the gate insulating film 12, of the plurality of recess insulators 14 is contiguous to the base region 9.

The plurality of recess insulators 14 each have an embedded portion 14a and a projection portion 14b. The embedded portion 14a is a part placed closer to the bottom wall side of the gate trench 11 than the first main surface 3. The projection portion 14b is a part placed at a higher position than the first main surface 3. The projection portion 14b may have a hollow toward the bottom wall side of the gate trench 11 in the upper end portion.

The semiconductor device 1A includes a plurality of n-type emitter regions 17 formed in a region along the trench gate structure 10 in a surficial portion of the base region 9. The plurality of emitter regions 17 are arranged on both sides of each of the trench gate structures 10 so as to be contiguous to each of the trench gate structures 10, respectively. In this embodiment, the plurality of emitter regions 17 are each arranged in a region between the pair of trench gate structures 10. The plurality of emitter regions 17 each have an n-type impurity concentration higher than the drift region 6.

The plurality of emitter regions 17 are formed at a distance from each other in the extending direction of each of the trench gate structures 10 so as to expose a part of the base region 9 from the first main surface 3. That is, the plurality of emitter regions 17 define a plurality of base intermediate regions 18 that are formed of a part of the base region 9 in the surficial portion of the first main surface 3. The plurality of emitter regions 17 are formed at a distance from the bottom portion of the base region 9 toward the first main surface 3 side. The plurality of emitter regions 17 have a bottom portion placed closer to the first main surface 3 side than the bottom portion of the plurality of electrode recess portions 15.

The plurality of emitter regions 17 are arrayed at a distance from each other in the extending direction of the trench gate structure 10 so as to face the plurality of electrode projection portions 16 in a direction (first direction X) perpendicular to the extending direction of the trench gate structure 10. Specifically, the plurality of emitter regions 17 are arrayed at a distance from the plurality of electrode recess portions 15 in the extending direction of the trench gate structure 10 so as not to face the plurality of electrode recess portions 15 in the direction (first direction X) perpendicular thereto.

That is, the plurality of emitter regions 17 are arrayed at positions at which the plurality of emitter regions 17 do not face the plurality of recess insulators 14, respectively. Also, the plurality of emitter regions 17 are arrayed in a matrix manner in a plan view. As a matter of course, the plurality of emitter regions 17 may be arrayed in a staggered manner in a case in which the plurality of electrode recess portions 15 (the plurality of recess insulators 14) are arrayed in a staggered manner.

In this embodiment, the plurality of emitter regions 17 are each formed in a belt shape extending in the extending direction of the trench gate structure 10 in a plan view. That is, each of the emitter regions 17 has a layout in which the length in the second direction Y is larger than the length in the first direction X in a plan view. Preferably, the length in the second direction Y of each of the emitter regions 17 exceeds the distance (trench pitch) in the first direction X between the plurality of trench gate structures 10.

With respect to the second direction Y, preferably, the length of each of the emitter regions 17 is equal to or more than the length of each of the electrode projection portions 16, and, particularly preferably, is more than the length of each of the electrode projection portions 16. Preferably, the length of each of the emitter regions 17 is equal to or more than the length of each of the recess insulators 14, and, particularly preferably, is more than the length of each of the recess insulators 14. Preferably, the length of each of the emitter regions 17 is equal to or more than the length of each of the base intermediate regions 18, and, particularly preferably, is more than the length of each of the base intermediate regions 18.

With respect to the second direction Y, the length of each of the emitter regions 17 may be not less than 1 μm and not more than 10 μm. Preferably, the length of each of the emitter regions 17 is 5 μm or less. Particularly preferably, the length of each of the emitter regions 17 is 3 μm or less. The region ratio of the plurality of emitter regions 17 in a region (one mesa portion) between the pair of trench gate structures 10 adjoining each other may be 70% or less. Preferably, the region ratio is 50% or less. Particularly preferably, the region ratio is 30% or less.

The semiconductor device 1A includes a plurality of n-type CS regions 19 (Carrier Storage regions) formed in a region directly under the base region 9 inside the chip 2 (drift region 6). The plurality of CS regions 19 have an n-type impurity concentration higher than the drift region 6. Preferably, the n-type impurity concentration of the plurality of CS regions 19 is lower than the emitter region 17. Preferably, the n-type impurity concentration of the plurality of CS regions 19 is lower than the p-type impurity concentration of the base region 9.

The plurality of CS regions 19 are arranged on both sides of each of the trench gate structures 10 so as to be contiguous to each of the trench gate structures 10, respectively, and are each formed in a belt shape extending along each of the trench gate structures 10 in a plan view. The plurality of CS regions 19 face the plurality of emitter regions 17 and the plurality of base intermediate regions 18 in the thickness direction of the chip 2.

The plurality of CS regions 19 are each formed in a region between the bottom portion of the base region 9 and a bottom wall of the trench gate structure 10 with respect to the thickness direction of the chip 2. Preferably, the plurality of CS regions 19 have a bottom portion placed closer to the base region 9 side than the bottom wall of the trench gate structure 10. Preferably, the bottom portion of the plurality of CS regions 19 is placed closer to the bottom wall side of the trench gate structure 10 than an intermediate portion of the trench gate structure 10.

The plurality of CS regions 19 promote the accumulation of carriers (holes) in a region directly under the plurality of trench gate structures 10. That is, the plurality of CS regions 19 promote on-resistance reduction and on-voltage reduction from the inside of the chip 2. The presence or absence of the CS region 19 is optional, and the CS region 19 may be excluded if necessary.

The semiconductor device 1A includes at least one (in this embodiment, a plurality of) p-type in-base region 20 formed in a region between the bottom portion of the base region 9 and the bottom portion of the emitter region 17 in the base region 9. In this embodiment, the single in-base region 20 is arranged in a region directly under the plurality of emitter regions 17 one by one. The plurality of in-base regions 20 have a p-type impurity concentration higher than the base region 9. Preferably, the p-type impurity concentration of the plurality of in-base regions 20 is equal to or less than the n-type impurity concentration of the emitter region 17, and, particularly preferably, is less than the n-type impurity concentration of the emitter region 17.

The plurality of in-base regions 20 are arranged on both sides of each of the trench gate structures 10 so as to be contiguous to each of the trench gate structures 10, respectively, and are each formed in a belt shape extending along each of the trench gate structures 10 in a plan view. In this embodiment, the plurality of in-base regions 20 are formed at a distance from the bottom portion of the base region 9 toward the first main surface 3 side, and face the drift region 6 (CS region 19) across a part of the base region 9. In this embodiment, the plurality of in-base regions 20 are connected to the emitter region 17 placed directly above the plurality of in-base regions 20.

Referring to FIG. 7, preferably, the plurality of in-base regions 20 are each formed narrower than the emitter region 17 placed directly on the plurality of in-base regions 20 in a plan view and in a cross-sectional view. That is, with respect to the second direction Y, preferably, the length of each of the in-base regions 20 is less than the length of each of the emitter regions 17. In a case in which the length of each of the emitter regions 17 is 10 μm or less, the length of each of the in-base regions 20 is less than 10 μm. In a case in which the length of each of the emitter regions 17 is 5 μm or less, the length of each of the in-base regions 20 is less than 5 μm. In a case in which the length of each of the emitter regions 17 is 3 μm or less, the length of each of the in-base regions 20 is less than 3 μm.

With respect to the second direction Y, a region distance D of each of the in-base regions 20 may be not less than 0.1 μm and not more than 5 μm under the condition that the region distance D of each of the in-base regions 20 is less than the length of each of the emitter regions 17. The region distance D is a distance between a peripheral edge of the in-base region 20 and a peripheral edge of the emitter region 17. Preferably, the region distance D is 2.5 μm or less. Particularly preferably, the region distance D is 1 μm or less. Preferably, the region distance D is 0.25 μm or more.

With respect to the second direction Y, preferably, the length of each of the in-base regions 20 is less than the length of each of the electrode projection portions 16. Preferably, the length of each of the in-base regions 20 is equal to or more than the length of each of the recess insulators 14, and, particularly preferably, is more than the length of each of the recess insulators 14. Preferably, the length of each of the in-base regions 20 is equal to or more than the length of each of the base intermediate regions 18, and, particularly preferably, is more than the length of each of the base intermediate regions 18.

The semiconductor device 1A includes at least one (in this embodiment, a plurality of) channel region 21, which is formed in the base region 9, and at least one (in this embodiment, a plurality of) non-channel region 22. The channel region 21 is a region having a comparatively low gate threshold voltage, and the non-channel region 22 is a region having a gate threshold voltage higher than the gate threshold voltage of the channel region 21. In other words, the channel region 21 is a region that serves as a current path by the inversion of the base region 9, and the non-channel region 22 is a region in which the inversion of the base region 9 does not easily occur.

The plurality of channel regions 21 are each formed in a region sandwiched between the plurality of in-base regions 20 in the base region 9. The plurality of non-channel regions 22 are each formed in a region other than the plurality of channel regions 21 in the base region 9 (i.e., are each formed in a region into which the plurality of in-base regions 20 have been introduced).

The in-base region 20 narrower than the emitter region 17 makes it possible to form the channel region 21 in a region between the bottom portion of the base region 9 and the bottom portion of the emitter region 17. Hence, it is possible to appropriately control the inversion and the non-inversion in the channel region 21, and, simultaneously, it is possible to appropriately inject electrons from the emitter region 17 into the channel region 21.

The semiconductor device 1A includes at least one (in this embodiment, a plurality of) chip recess portion 23 formed in the first main surface 3. The chip recess portion 23 may be regarded as a component of the first main surface 3. The plurality of chip recess portions 23 are each formed in a region between the plurality of emitter regions 17, and expose the plurality of emitter regions 17 and the base intermediate region 18. The plurality of chip recess portions 23 are formed at a distance from the plurality of in-base regions 20 in a surface direction of the first main surface 3 (specifically, the second direction Y).

That is, the plurality of chip recess portions 23 are formed at a distance from the plurality of electrode projection portions 16 so as to be adjacent to the plurality of electrode recess portions 15 (recess insulator 14). In this embodiment, the plurality of chip recess portions 23 are formed in a region sandwiched between the plurality of electrode recess portions 15 (recess insulators 14) adjoining each other in the first direction X, and are not arranged in a region sandwiched between the plurality of electrode projection portions 16.

A configuration of the single chip recess portion 23 will be hereinafter described. The chip recess portion 23 has a recess sidewall 24 and a recess bottom wall 25. The recess sidewall 24 is defined by the chip 2 and by the plurality of recess insulators 14 (gate insulating film 12). The recess sidewall 24 is formed at a distance from the plurality of in-base regions 20 in the surface direction of the first main surface 3 (specifically, the second direction Y), and exposes the plurality of emitter regions 17.

That is, the recess sidewall 24 does not expose the in-base region 20. In this embodiment, the recess sidewall 24 exposes only the plurality of recess insulators 14 (gate insulating film 12) and the plurality of emitter regions 17.

The recess bottom wall 25 is defined by the chip 2. The recess bottom wall 25 is placed closer to the bottom wall side of the plurality of trench gate structures 10 than an upper end portion of the plurality of recess insulators 14, and is placed closer to the first main surface 3 side than the bottom portion of the base region 9. Preferably, the recess bottom wall 25 is placed closer to the first main surface 3 side than a bottom portion of the in-base region 20. Particularly preferably, the recess bottom wall 25 is placed closer to the first main surface 3 side than the bottom portion of the plurality of emitter regions 17.

The recess bottom wall 25 exposes the base region 9 (base intermediate region 18). Preferably, the recess bottom wall 25 exposes only the base region 9. With respect to the second direction Y, preferably, each of the chip recess portions 23 has a length equal to or less than the length of each of the electrode recess portions 15 (recess insulator 14). Particularly preferably, the length of each of the chip recess portions 23 is less than the length of each of the electrode recess portions 15 (recess insulator 14).

The semiconductor device 1A includes a main surface insulating film 30 that selectively covers the first main surface 3. The main surface insulating film 30 may include at least one among a silicon oxide film, a silicon nitride film, a silicon oxynitride film, and an aluminum oxide film. Preferably, the main surface insulating film 30 includes a silicon oxide film made of an oxide of the chip 2. Particularly preferably, the main surface insulating film 30 has a single-layer structure consisting of a single insulating film.

The main surface insulating film 30 may extend as a film along the first main surface 3, and may be continuous with the peripheral edge (first to fourth side surfaces 5A to 5D) of the chip 2. The main surface insulating film 30 exposes the plurality of trench gate structures 10 and the plurality of chip recess portions 23 (plurality of base intermediate regions 18), and covers the plurality of emitter regions 17. The main surface insulating film 30 is connected to the gate insulating film 12, and exposes the gate embedded electrode 13.

The semiconductor device 1A includes the interlayer insulating film 31 that covers the main surface insulating film 30. The interlayer insulating film 31 may include at least one among a silicon oxide film, a silicon nitride film, a silicon oxynitride film, and an aluminum oxide film. The interlayer insulating film 31 may include at least one among an NSG (Non-doped Silicate Glass) film, a PSG (Phosphor Silicate Glass) film, and a BPSG (Boron Phosphor Silicate Glass) film as an example of the silicon oxide film. The interlayer insulating film 31 may have a single-layer structure consisting of a single insulating film or a laminated structure including a plurality of insulating films. The interlayer insulating film 31 has a thickness exceeding the thickness of the main surface insulating film 30.

The interlayer insulating film 31 may extend as a film along the first main surface 3, and may be continuous with the peripheral edge (first to fourth side surfaces 5A to 5D) of the chip 2. The interlayer insulating film 31 covers the main surface insulating film 30 and the plurality of trench gate structures 10. The interlayer insulating film 31 covers the plurality of electrode projection portions 16 (gate embedded electrode 13) so as to expose a part of the plurality of recess insulators 14 in each of the trench gate structures 10. Specifically, the interlayer insulating film 31 covers the whole area of the plurality of electrode projection portions 16 so as to be continuous with the plurality of recess insulators 14.

In this embodiment, the interlayer insulating film 31 is formed integrally with the plurality of recess insulators 14. In other words, the plurality of recess insulators 14 are each formed by a part, which is located inside the plurality of electrode recess portions 15, of the interlayer insulating film 31. As a matter of course, the interlayer insulating film 31 may be formed so as to be structurally independent of the plurality of recess insulators 14. In this case, the interlayer insulating film 31 may be made of the same insulator as the plurality of recess insulators 14, or may be made of an insulator differing from that of the recess insulator 14.

The interlayer film 31 has an insulating insulating main surface 32 extending along the first main surface 3. The insulating main surface 32 is placed at a higher position than the upper end portion of the plurality of recess insulators 14. The interlayer insulating film 31 has a plurality of connection holes 33. The plurality of connection holes 33 are each formed in a belt shape extending in the first direction X, and are formed at a distance from each other in the second direction Y. That is, the plurality of connection holes 33 are arrayed in a stripe shape extending in the first direction X.

The plurality of connection holes 33 extend in the first direction X so as to expose the plurality of recess insulators 14 and the plurality of chip recess portions 23, and intersect (specifically, perpendicularly intersect) the plurality of trench gate structures 10. The plurality of connection holes 33 communicate with the plurality of chip recess portions 23. The plurality of connection holes 33 expose only the plurality of recess insulators 14 (gate insulating film 12) in an intersection portion with the plurality of trench gate structures 10. That is, the plurality of connection holes 33 are formed at a distance from the plurality of electrode projection portions 16 in the surface direction (second direction Y) of the first main surface 3, and do not expose the plurality of electrode projection portions 16.

The plurality of connection holes 33 expose only the plurality of emitter regions 17 and the plurality of base intermediate regions 18 in an intersection portion (communication portion) with the plurality of chip recess portions 23. That is, the plurality of connection holes 33 are formed at a distance from the in-base region 20 in the surface direction (second direction Y) of the first main surface 3, and do not expose the in-base region 20.

With respect to the second direction Y, the width of each of the connection holes 33 is less than the length of each of the recess insulators 14 (electrode recess portion 15). With respect to the second direction Y, preferably, the width of each of the connection holes 33 is substantially equal to the length of each of the chip recess portions 23. That is, preferably, each of the connection holes 33 has a wall surface continuous with the recess sidewall 24 of the chip recess portion 23.

The semiconductor device 1A includes a gate electrode 35 arranged on the interlayer insulating film 31 so as to be electrically connected to the plurality of trench gate structures 10. Specifically, the gate electrode 35 includes at least one (in this embodiment, one) gate terminal electrode 36 and at least one (in this embodiment, a plurality of) gate wiring electrode 37. The gate terminal electrode 36 is a part to which a gate potential is given from the outside. The to-be-arranged place of the gate terminal electrode 36 is optional. In this embodiment, the gate terminal electrode 36 is arranged at a position adjacent to a central portion of the third side surface 5C in a plan view.

The gate terminal electrode 36 may be arranged at an arbitrary corner portion of the chip 2 in a plan view or may be arranged at a central portion of the chip 2 in a plan view. The planar shape of the gate terminal electrode 36 is optional. In this embodiment, the gate terminal electrode 36 is formed in a quadrangular shape in a plan view. The gate terminal electrode 36 faces the chip 2 across the interlayer insulating film 31 and the main surface insulating film 30.

The plurality of gate wiring electrodes 37 are led out from the gate terminal electrode 36 onto the interlayer insulating film 31. In this embodiment, the plurality of gate wiring electrodes 37 include first to third gate wiring electrodes 37A to 37C.

The first gate wiring electrode 37A is led out in a belt shape from the gate terminal electrode 36 toward the first side surface 5A side in a plan view, and extends along the first side surface 5A and the third side surface 5C. The second gate wiring electrode 37B is led out in a belt shape from the gate terminal electrode 36 toward the second side surface 5B side in a plan view, and extends along the first side surface 5A and the second side surface 5B. The third gate wiring electrode 37C is led out in a belt shape from the gate terminal electrode 36 toward the central portion of the chip 2 in a plan view.

The plurality of gate wiring electrodes 37 penetrate the interlayer insulating film 31 and are electrically connected to the plurality of trench gate structures 10 (gate embedded electrode 13). The plurality of gate wiring electrodes 37 may be directly connected to the plurality of trench gate structures 10 (gate embedded electrode 13), or may be connected to the plurality of trench gate structures 10 (gate embedded electrode 13) through a conductor film. A gate potential applied to the gate terminal electrode 36 is given to the plurality of trench gate structures 10 through the plurality of gate wiring electrodes 37.

The semiconductor device 1A includes the emitter electrode 40 arranged on the interlayer insulating film 31 at a distance from the gate electrode 35 so as to be electrically connected to the base region 9 and to the plurality of emitter regions 17. Specifically, the emitter electrode 40 includes at least one (in this embodiment, a plurality of) emitter connection electrode 41 and at least one (in this embodiment, one) emitter terminal electrode 42.

The plurality of emitter connection electrodes 41 are arranged in the plurality of connection holes 33, respectively. The plurality of emitter connection electrodes 41 each have a planar shape and a sectional shape that match those of the plurality of connection holes 33. That is, the plurality of emitter connection electrodes 41 are each formed in a belt shape extending in the first direction X, and are arrayed at a distance from each other in the second direction Y. Also, the plurality of emitter connection electrodes 41 are arrayed in a stripe shape extending in the first direction X.

The plurality of emitter connection electrodes 41 intersect (specifically, perpendicularly intersect) the plurality of trench gate structures 10. The plurality of emitter connection electrodes 41 have a portion that intersects (specifically, perpendicularly intersects) the plurality of trench gate structures 10 and a portion that intersects (specifically, perpendicularly intersects) the plurality of chip recess portions 23.

Also, the plurality of emitter connection electrodes 41 have a portion that is placed inside the plurality of connection holes 33 and a portion that is placed inside the plurality of chip recess portions 23. The plurality of emitter connection electrodes 41 cover the plurality of recess insulators 14 and the plurality of chip recess portions 23 in the plurality of connection holes 33.

Specifically, the plurality of emitter connection electrodes 41 have a portion that covers the plurality of recess insulators 14 in an intersection portion with the plurality of trench gate structures 10. The plurality of emitter connection electrodes 41 face the plurality of gate embedded electrodes 13 across the plurality of recess insulators 14 with respect to the depth direction of the plurality of trench gate structures 10. The plurality of emitter connection electrodes 41 are connected only to the plurality of recess insulators 14 (gate insulating film 12) in the intersection portion with the plurality of trench gate structures 10.

That is, the plurality of emitter connection electrodes 41 are formed at a distance from the plurality of electrode projection portions 16 in the surface direction (second direction Y) of the first main surface 3, and are electrically separated from the plurality of electrode projection portions 16. Preferably, the plurality of emitter connection electrodes 41 face each other in the second direction Y across a part of the interlayer insulating film 31, and do not face the plurality of electrode projection portions 16 in the second direction Y. As a matter of course, a part (for example, lower end portion) of the plurality of emitter connection electrodes 41 may face the electrode projection portion 16 across the recess insulator 14.

The plurality of emitter connection electrodes 41 have a portion that covers the plurality of recess insulators 14 (gate insulating film 12), the base region 9 (plurality of base intermediate regions 18), and the plurality of emitter regions 17 in an intersection portion with the plurality of chip recess portions 23. The plurality of emitter connection electrodes 41 are electrically connected to the base region 9 (plurality of base intermediate regions 18) and to the plurality of emitter regions 17 inside the plurality of chip recess portions 23.

The plurality of emitter connection electrodes 41 are arranged at a distance from the plurality of in-base regions 20 in the surface direction (second direction Y) of the first main surface 3, and are electrically connected to the plurality of in-base regions 20 through a part of the plurality of base regions 9. That is, the plurality of emitter connection electrodes 41 are not directly connected to the plurality of in-base regions 20. With respect to the second direction Y, the width of each of the emitter connection electrodes 41 is less than length of each of the recess insulators 14 (electrode recess portion 15). With respect to the second direction Y, preferably, the width of each of the connection 41 emitter electrodes is substantially equal to the length of each of the chip recess portions 23.

The emitter terminal electrode 42 is arranged on the interlayer insulating film 31 at a distance from the gate electrode 35, and is connected to the plurality of emitter connection electrodes 41. In this embodiment, the emitter terminal electrode 42 is formed integrally with the plurality of emitter connection electrodes 41. That is, a part, which is located inside the plurality of connection holes 33, of the emitter electrode 40 is formed as the plurality of emitter connection electrodes 41, and a part, which is located on an interlayer main surface, of the emitter electrode 40 is formed as the emitter terminal electrode 42.

In this embodiment, the emitter electrode 40 has a laminated structure including a first electrode film 43 and a second electrode film 44 that are laminated in that order from the chip 2 side. The first electrode film 43 is formed as a film along the insulating main surface 32 and along the wall surface of the plurality of connection holes 33. The first electrode film 43 covers the plurality of recess insulators 14 as a film, the wall surface of the plurality of chip recess portions 23, and the wall surface of the plurality of connection holes 33 inside the plurality of connection holes 33.

The first electrode film 43 may include a Ti-based metal film. The first electrode film 43 may have a single-layer structure consisting of a Ti film or a TiN film. The first electrode film 43 may have a laminated structure including a Ti film and a TiN film that are laminated in an arbitrary order.

The second electrode film 44 has a thickness exceeding the thickness of the first electrode film 43, and is formed as a film along the first electrode film 43. The second electrode film 44 includes a portion that is placed on the insulating main surface 32 and a portion that is placed inside the plurality of connection holes 33. The second electrode film 44 covers the insulating main surface 32 with the first electrode film 43 between the second electrode film 44 and the insulating main surface 32. Inside the plurality of connection holes 33, the second electrode film 44 covers the plurality of recess insulators 14 as a film, the wall surface of the plurality of chip recess portions 23, and the wall surface of the plurality of connection holes 33 with the first electrode film 43 between the second electrode film 44 and the plurality of connection holes 33.

The second electrode film 44 may include an Al-based metal film or a Cu-based metal film. The Al-based metal film may include at least one among a pure Al film (whose purity is 99% or more), an AlCu alloy film, an AlSi alloy film, and an AlSiCu alloy film. The Cu-based metal film may be a pure Cu film (whose purity is 99% or more) or a Cu alloy film. The AlCu alloy film and the AlSiCu alloy film are examples of the Cu alloy film.

As thus described, the plurality of emitter connection electrodes 41 are formed by a laminated film consisting of the first electrode film 43 and the second electrode film 44, and the emitter terminal electrode 42 is formed by a laminated film consisting of the first electrode film 43 and the second electrode film 44. That is, the emitter terminal electrode 42 is formed integrally with the plurality of emitter connection electrodes 41.

The semiconductor device 1A includes a collector electrode 45 covering the second main surface 4. The collector electrode 45 is electrically connected to the collector region 8 exposed from the second main surface 4. The collector electrode 45 makes an ohmic contact with the collector region 8. The collector electrode 45 may cover the whole area of the second main surface 4 so as to be continuous with the peripheral edge (first to fourth side surfaces 5A to 5D) of the chip 2.

The collector electrode 45 may include at least one among a Ti film, an Ni film, a Pd film, an Au film, an Ag film, and an Al film. The collector electrode 45 may have a single-film structure including a Ti film, an Ni film, an Au film, an Ag film, or an Al film. The collector electrode 45 may have a laminated structure in which at least two among a Ti film, an Ni film, a Pd film, an Au film, an Ag film, and an Al film are laminated in an arbitrary manner. Preferably, the collector electrode 45 includes a Ti film that directly covers at least the second main surface 4. As an example, the collector electrode 45 may include a Ti film, an Ni film, a Pd film, and an Au film that are laminated in that order from the second main surface 4 side.

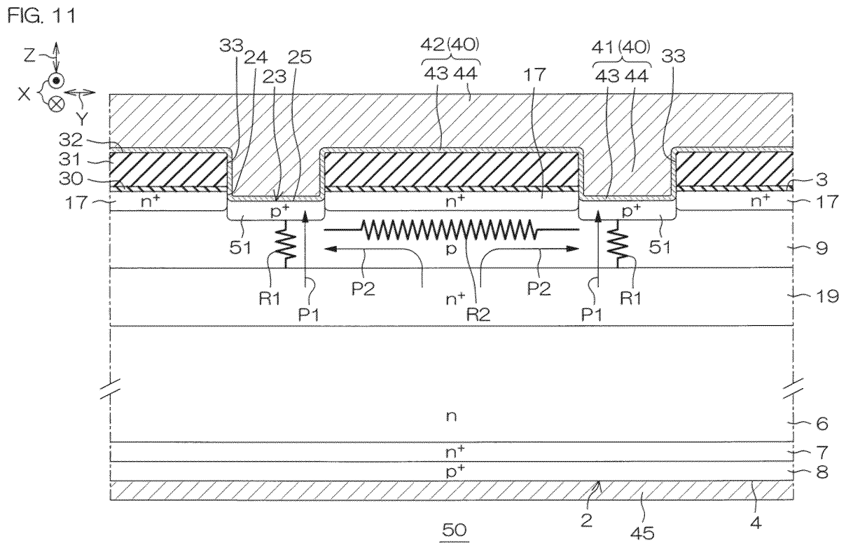

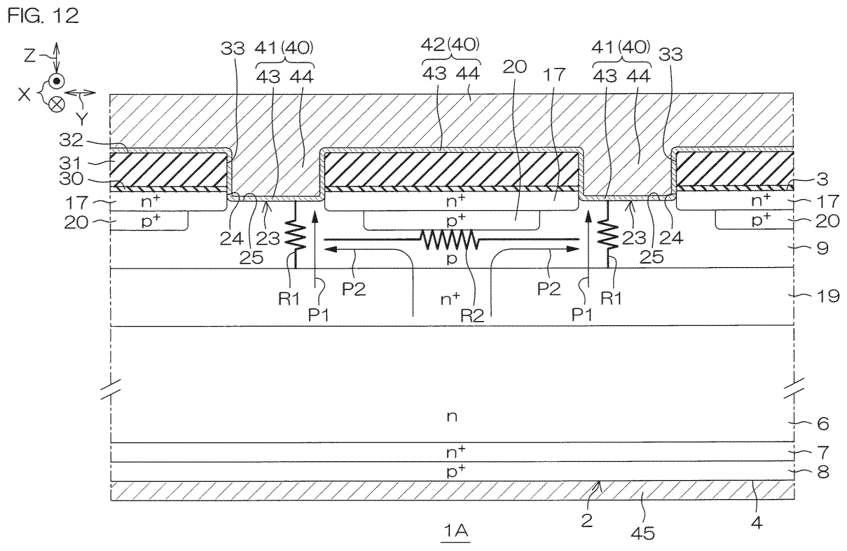

FIG. 11 is a cross-sectional view of a semiconductor device 50 according to a reference example, which is shown together with resistance symbols. FIG. 12 is a cross-sectional view of the semiconductor device 1A according to the first embodiment, which is shown together with resistance symbols. Referring to FIG. 11, the semiconductor device 50 according to the reference example does not have the in-base region 20 in a region directly under the emitter region 17. The semiconductor device 50 includes at least one (in this embodiment, a plurality of) intermediate in-base region 51 formed in a region (base intermediate region 18) between the plurality of emitter regions 17 in the surficial portion of the base region 9.

Specifically, the plurality of intermediate in-base regions 51 are each formed in a region along the bottom wall of the plurality of chip recess portions 23 in the base region 9. The plurality of emitter connection electrodes 41 are electrically connected to the plurality of intermediate in-base regions 51 and to the plurality of emitter regions 17 in the plurality of chip recess portions 23.

A Hall current flows from the drift region 6 to the emitter connection electrode 41 through the base region 9 during ON-operation. The Hall current passes through a first current path P1 and a second current path P2 in the base region 9. The first current path P1 is a path that extends in the thickness direction of the chip 2 between the drift region 6 and the emitter connection electrode 41. The first current path P1 has a comparatively-small first parasitic resistance R1.

The second current path P2 is a path that extends in the surface direction of the first main surface 3 in a region directly under the emitter region 17. The length of the second current path P2 exceeds the length of the first current path P1. The second current path P2 has a second parasitic resistance R2 larger than the first parasitic resistance R1. In the semiconductor device 50, a comparatively-large voltage drop (I×R2) occurs because of the second parasitic resistance R2 during ON-operation.

That is, in the semiconductor device 50, a parasitic NPN transistor is controlled to reach a false-ON state by a voltage drop (I×R2) caused by the second parasitic resistance R2, and it becomes impossible to control the IGBT structure by a gate potential. The parasitic NPN transistor includes the n-type emitter region 17, the p-type base region 9, and the n-type drift region 6 (CS region 19). As thus described, the semiconductor device 50 has the structural risk of being destroyed because of a latch-up phenomenon (false-ON state) of the parasitic NPN transistor.

The second parasitic resistance R2 is raised by enlarging the length (second current path P2) of the emitter region 17, and is lowered by reducing the length (second current path P2) of the emitter region 17. Therefore, in a case in which the length (ratio per unit area) of the emitter region 17 is increased, an accumulative number of carriers (Hall current) in a region directly under the emitter region 17 will be increased because of a rise in the second parasitic resistance R2. That is, an induced risk of a latch-up phenomenon increases as a result of a rise in built-in voltage.

On the other hand, referring to FIG. 12 etc., the semiconductor device 1A includes the chip 2, the p-type base region 9, the trench gate structure 10, the n-type emitter region 17, the p-type in-base region 20, the interlayer insulating film 31, and the emitter connection electrode 41. The chip 2 has the first main surface 3. The base region 9 is formed in the surficial portion of the first main surface 3. The trench gate structure 10 is formed in the first main surface 3 so as to penetrate the base region 9. The emitter region 17 is formed in a region along the trench gate structure 10 in the surficial portion of the base region 9.

The in-base region 20 is formed in a region between the bottom portion of the base region 9 and the bottom portion of the emitter region 17 in the base region 9. The in-base region 20 has a p-type impurity concentration higher than the base region 9. The interlayer insulating film 31 covers the first main surface 3. The interlayer insulating film 31 has the connection hole 33 that exposes a part of the emitter region 17. The connection hole 33 is formed at a distance from the in-base region 20 in a direction along the first main surface 3. The emitter connection electrode 41 is arranged in the connection hole 33. The emitter connection electrode 41 is electrically connected to the base region 9 and to the emitter region 17 in the connection hole 33.

This structure makes it possible to reduce the second parasitic resistance R2 by the in-base region 20 that is higher in concentration than the base region 9. Hence, it is possible to provide the semiconductor device 1A capable of improving electrical properties. Also, this structure makes it possible to suppress the accumulation of carriers in a region directly under the emitter region 17 by reducing the second parasitic resistance R2, thus making it possible to suppress a fall in short-circuit resistance capacity, which is caused by a latch-up phenomenon. The risk of the latch-up phenomenon is reduced by adjusting the layout (configuration, length, formation place, positional relationship, etc.) of both the emitter region 17 and the in-base region 20. Therefore, it is possible to improve electrical properties also from this viewpoint.

Preferably, the in-base region 20 is formed narrower than the emitter region 17. The in-base region 20 narrower than the emitter region 17 makes it possible to form the channel region 21 in a region between the bottom portion of the base region 9 and the bottom portion of the emitter region 17. Hence, it is possible to appropriately control the inversion and the non-inversion of the channel region 21, and, at the same time, it is possible to appropriately inject carriers (electrons) into the channel region 21 from the emitter region 17. The in-base region 20 may be connected to the emitter region 17.

Preferably, the connection hole 33 intersects the trench gate structure 10 in a plan view. In this case, preferably, the emitter connection electrode 41 intersects the trench gate structure 10 in a plan view. With this structure, there is no need to form the emitter connection electrode 41 at a distance from the trench gate structure 10, hence making it possible to lessen limitations on design rules imposed by the dimensional tolerance of the emitter connection electrode 41 with respect to the trench gate structure 10. For example, when the plurality of trench gate structures 10 are formed, it is possible to narrow the pitch of the plurality of trench gate structures 10. Therefore, it is possible to provide the semiconductor device 1A capable of improving electrical properties while being miniaturized.

Preferably, the semiconductor device 1A includes the chip recess portion 23 formed in the first main surface 3 so as to expose the emitter region 17. In this case, preferably, the connection hole 33 communicates with the chip recess portion 23. Preferably, the emitter connection electrode 41 includes a portion that is located inside the connection hole 33 and a portion that is located inside the chip recess portion 23. Preferably, the chip recess portion 23 has a bottom wall closer to the first main surface 3 side than the bottom portion of the base region 9. Preferably, the bottom wall of the chip recess portion 23 is placed closer to the first main surface 3 side than the bottom portion of the emitter region 17.

Preferably, the trench gate structure 10 includes the gate trench 11, the gate insulating film 12, the gate embedded electrode 13, the electrode recess portion 15, and the recess insulator 14. The gate trench 11 is formed in the first main surface 3. The gate insulating film 12 covers the wall surface of the gate trench 11. The gate embedded electrode 13 is embedded in the gate trench 11 with the gate insulating film 12 between the gate embedded electrode 13 and the gate trench 11.

The electrode recess portion 15 is formed at an electrode surface of the gate embedded electrode 13. The recess insulator 14 covers the electrode recess portion 15. In the thus formed structure, preferably, the interlayer insulating film 31 covers the gate embedded electrode 13 so as to be connected to the recess insulator 14. Also, preferably, the emitter connection electrode 41 has a portion that faces the gate embedded electrode 13 across the recess insulator 14.

Preferably, the in-base region 20 is formed at a distance from the recess insulator 14. Preferably, the connection hole 33 exposes the recess insulator 14 and the emitter region 17. Preferably, the recess insulator 14 has a portion that faces the base region 9 in the surface direction of the first main surface 3.

Preferably, the recess insulator 14 has the embedded portion 14a placed closer to the bottom wall side of the gate trench 11 than the first main surface 3 and the projection portion 14b placed at a higher position than the first main surface 3 in a cross-sectional view. Preferably, the interlayer insulating film 31 has the insulating main surface 32 placed at a higher position than the upper end portion (projection portion 14b) of the recess insulator 14.

Preferably, the semiconductor device 1A additionally includes the emitter electrode 40 covering the interlayer insulating film 31. The emitter electrode 40 may integrally include the emitter connection electrode 41 arranged inside the connection hole 33 and the emitter terminal electrode 42 covering the interlayer insulating film 31.

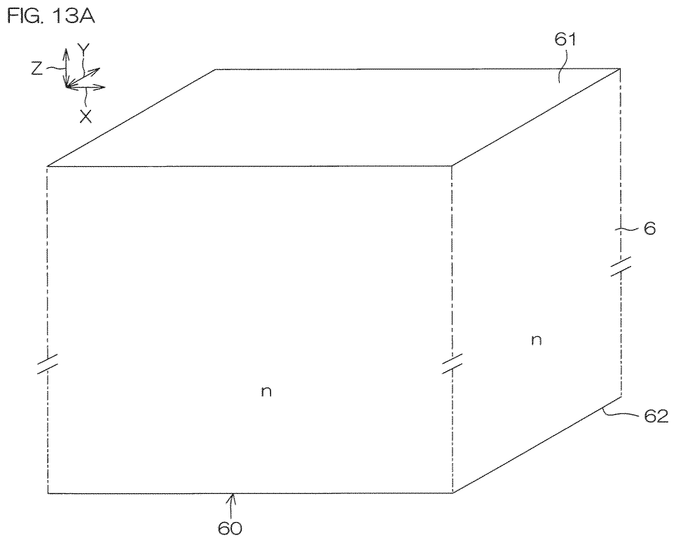

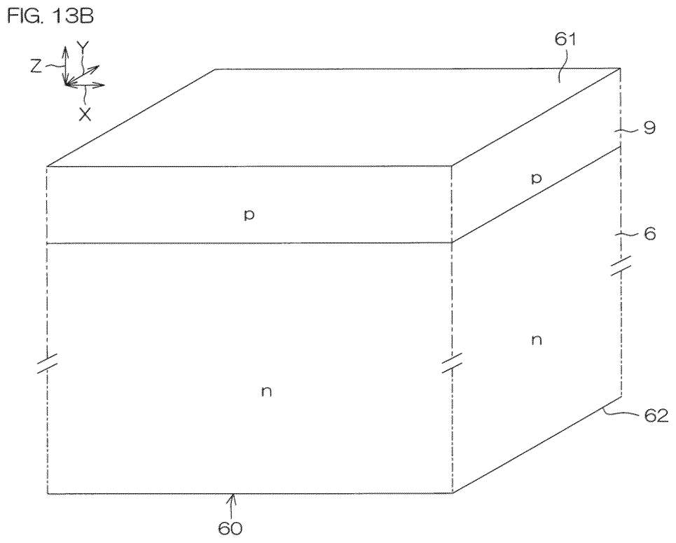

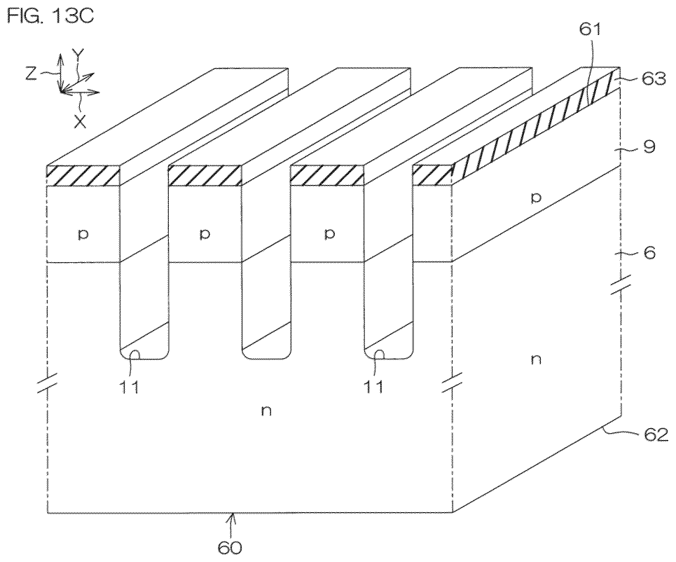

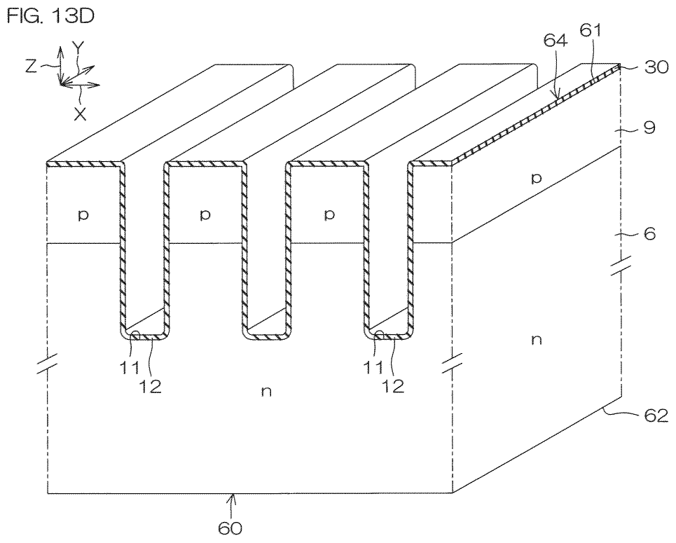

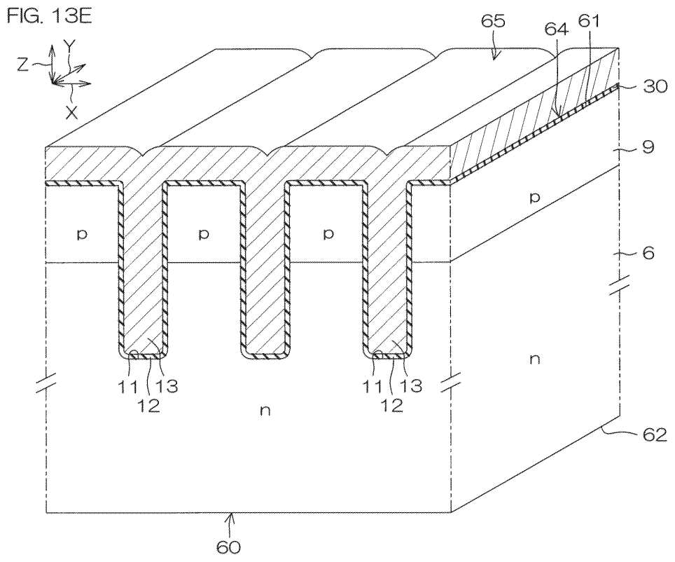

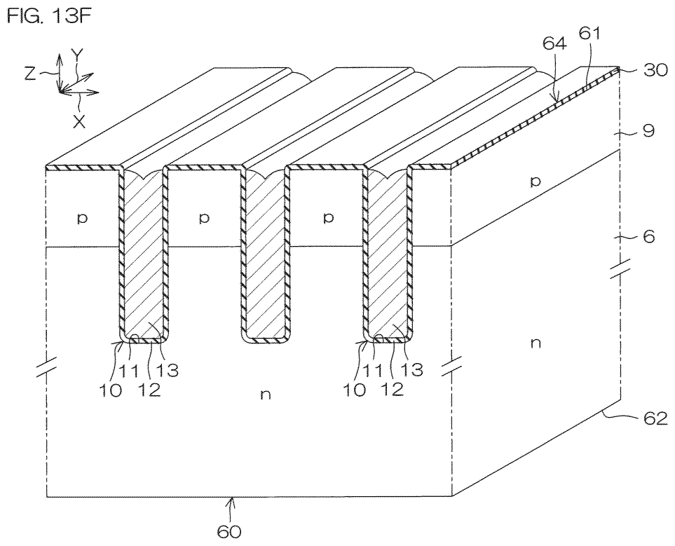

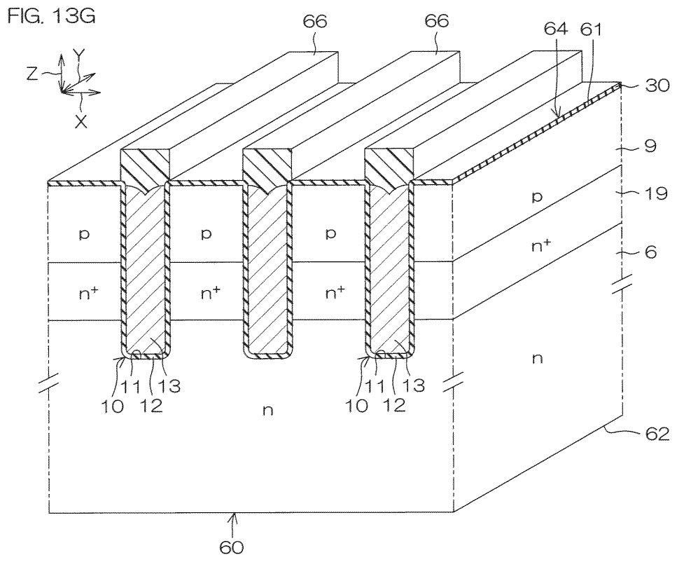

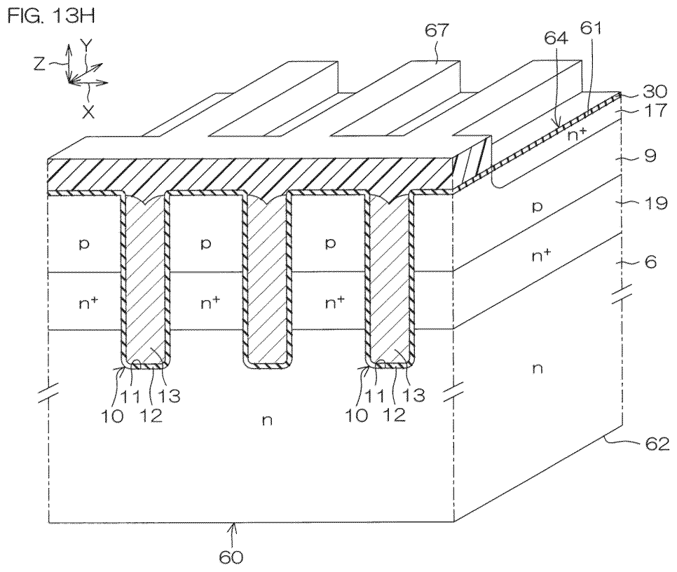

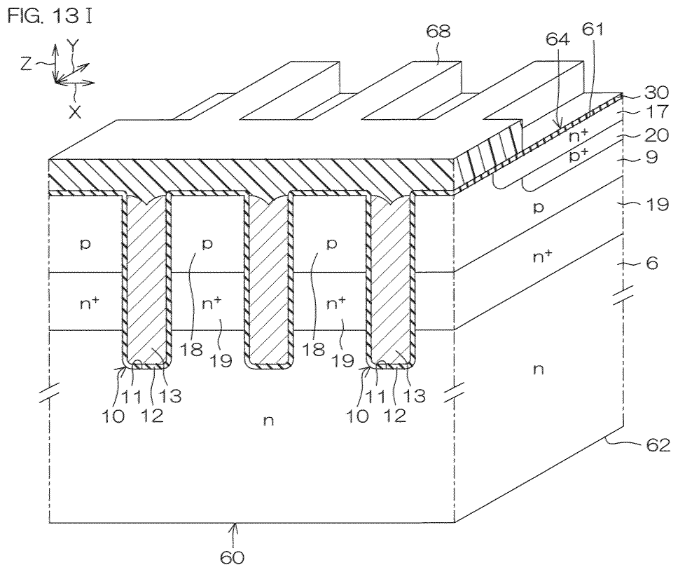

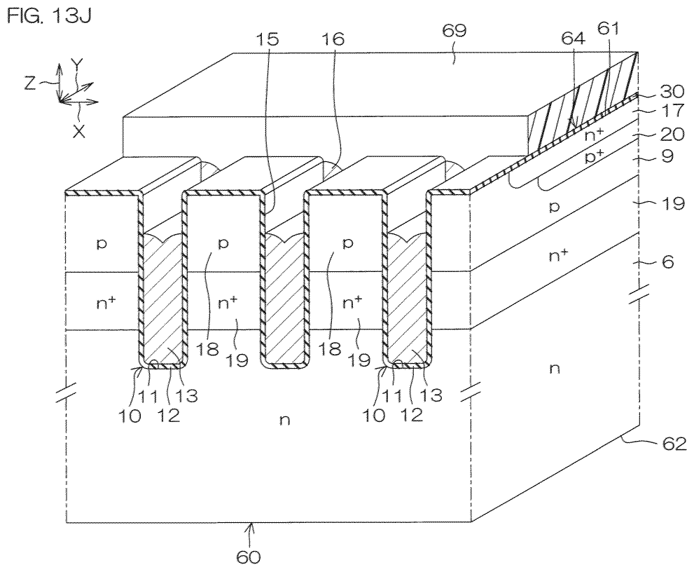

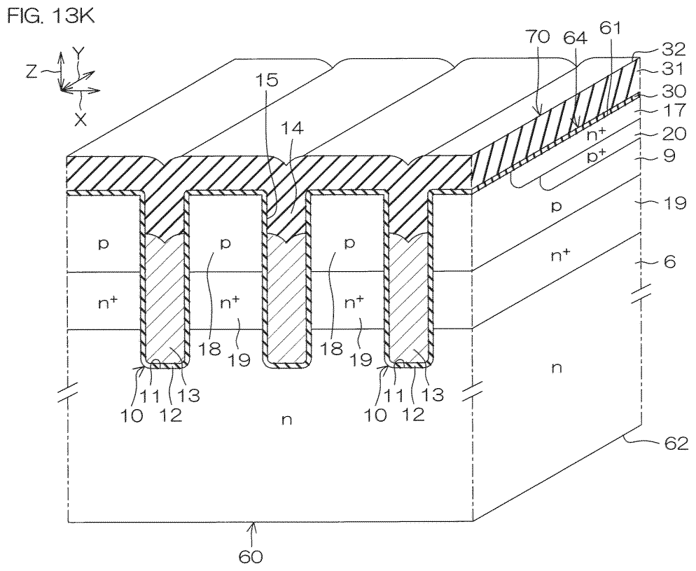

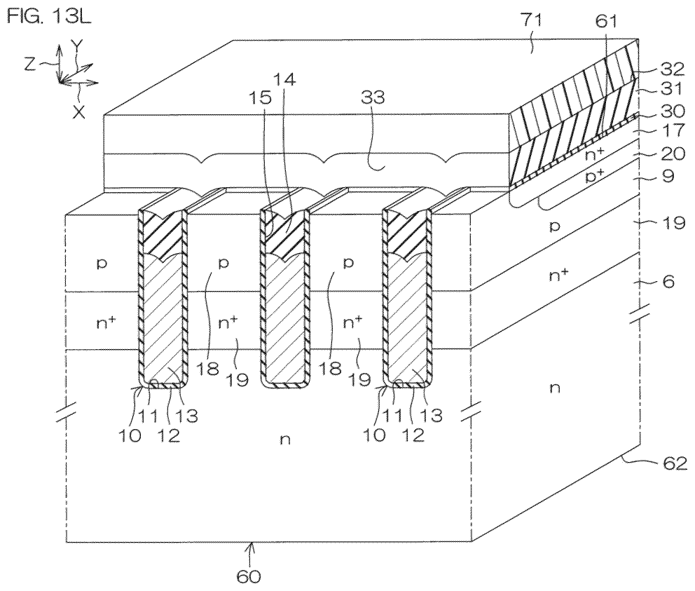

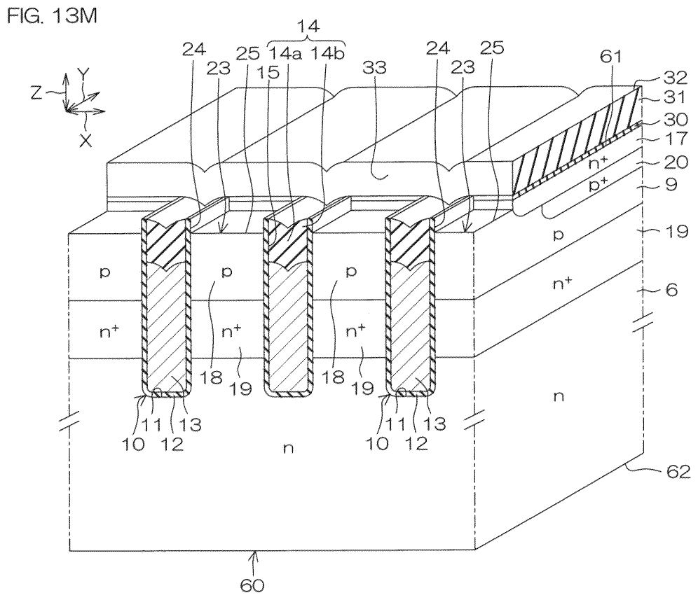

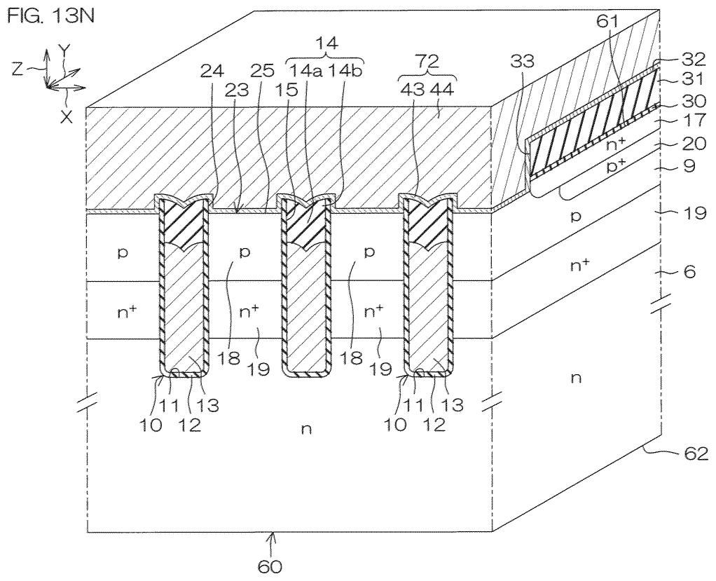

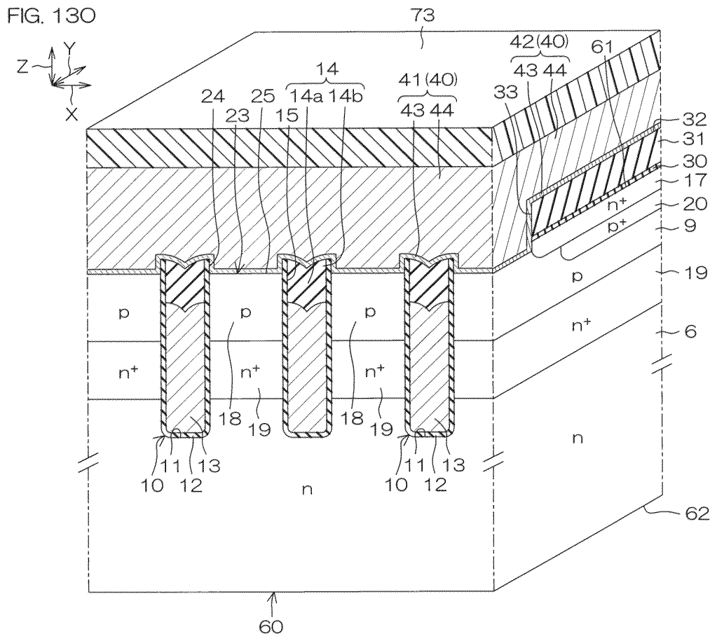

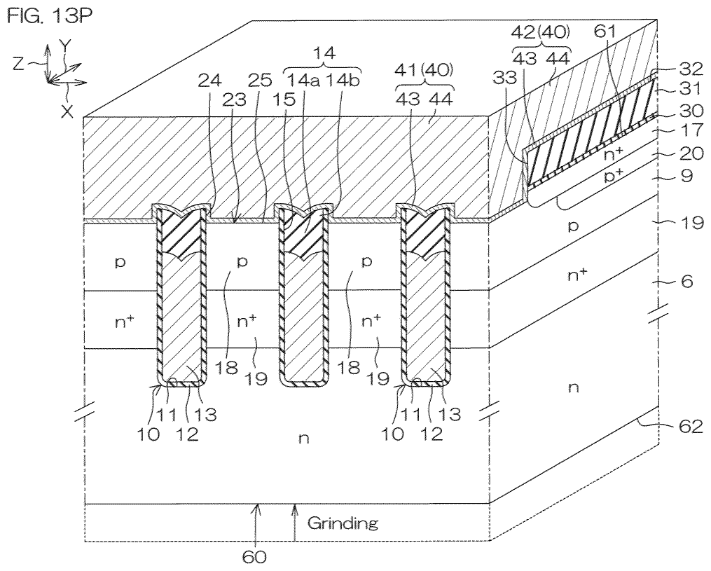

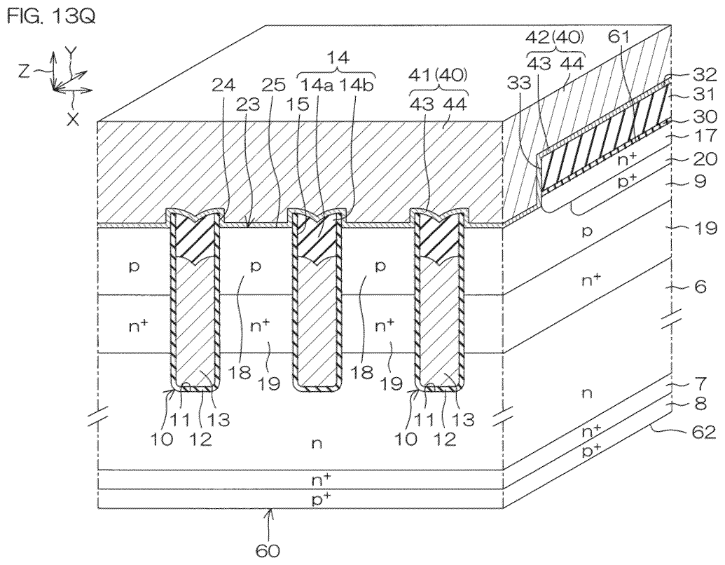

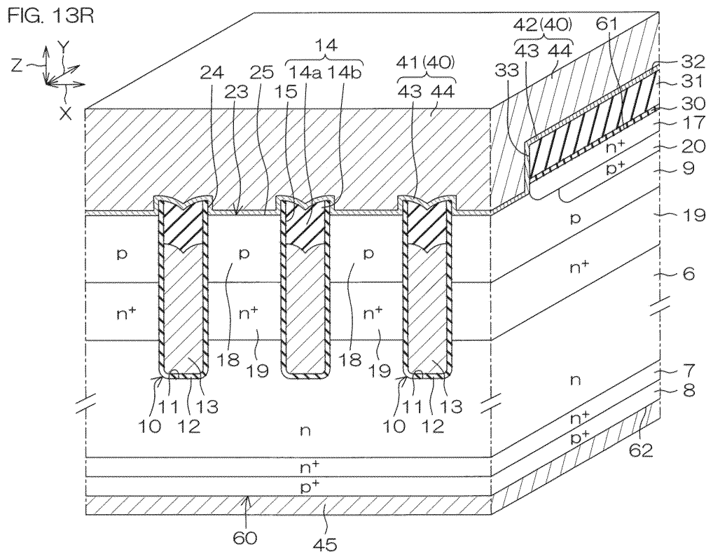

FIGS. 13A to 13R are cross-sectional perspective views showing an example of a method for manufacturing the semiconductor device 1A shown in FIG. 1. A detailed description of each of the structures formed in the steps of FIGS. 13A to 13R has been given as above, and hence is omitted or simplified. The process sequence (particularly, the order of the formation steps of the p-type semiconductor region and the n-type semiconductor region) shown in FIGS. 13A to 13R is an example, and may be appropriately replaced. In the following description, the term “mask” includes either one or both of an “organic insulation mask” and an “inorganic insulation mask.”

Referring to FIG. 13A, an n-type wafer 60 serving as a base of the plurality of chips 2 is prepared. In other words, the wafer 60 in which the n-type drift region 6 is beforehand formed in the whole area is prepared. The wafer 60 has a first wafer main surface 61 on one side and a second wafer main surface 62 on the other side. The first wafer main surface 61 and the second wafer main surface 62 correspond to the first main surface 3 and the second main surface 4 of the chip 2, respectively.

Next, referring to FIG. 13B, the p-type base region 9 is formed in a surficial portion of the first wafer main surface 61. The base region 9 may be formed by introducing a p-type impurity to the surficial portion of the first wafer main surface 61 through a mask (not shown) having a predetermined pattern.

Next, referring to FIG. 13C, a first mask 63 having a predetermined pattern is formed on the first wafer main surface 61. The first mask 63 has a layout that exposes regions in which the plurality of gate trenches 11 are to be formed and that covers regions other than these regions. Next, an unnecessary portion of the wafer 60 is removed by an etching method through the first mask 63.

The etching method may be a wet etching method and/or a dry etching method. The unnecessary portion of the wafer 60 is removed until the drift region 6 is exposed, upon penetrating the base region 9. Hence, the plurality of gate trenches 11 that penetrate the base region 9 so as to reach the drift region 6 are formed. Thereafter, the first mask 63 is removed.

Next, referring to FIG. 13D, a first base insulating film 64 is formed on the first wafer main surface 61. The first base insulating film 64 includes the plurality of gate insulating films 12 and the main surface insulating film 30. The first base insulating film 64 is formed as a film along the inner wall of the first wafer main surface 61 and the plurality of gate trenches 11. In this embodiment, the first base insulating film 64 includes a silicon oxide film. The first base insulating film 64 may be formed by an oxidation treatment method (for example, thermal oxidation treatment method) and/or a CVD (Chemical Vapor Deposition) method.

Next, referring to FIG. 13E, a first base electrode film 65 is formed on the first base insulating film 64. The first base electrode film 65 serves as a base of the gate embedded electrode 13. The first base electrode film 65 is embedded in the plurality of gate trenches 11 with the first base insulating film 64 between the first base electrode film 65 and the gate trench 11, and covers the first wafer main surface 61 as a film. In this embodiment, the first base insulating film 64 includes a polysilicon film. The first base electrode film 65 may be formed by a CVD method.

Next, referring to FIG. 13F, an unnecessary portion of the first base electrode film 65 is removed by an etching method. The etching method may be a wet etching method and/or a dry etching method. The unnecessary portion of the first base electrode film 65 is removed until the main surface insulating film 30 is exposed. Hence, the plurality of gate embedded electrodes 13 are formed.

Next, referring to FIG. 13G, a second mask 66 having a predetermined pattern is formed on the first wafer main surface 61. The second mask 66 exposes regions in which the plurality of CS regions 19 are to be formed, and covers regions (plurality of gate embedded electrodes 13 and main surface insulating film 30) other than these regions. Next, an n-type impurity is introduced into the wafer 60 through the second mask 66. Hence, the plurality of CS regions 19 are formed. Thereafter, the second mask 66 is removed.

Next, referring to FIG. 13H, a third mask 67 having a predetermined pattern is formed on the first wafer main surface 61. The third mask 67 exposes regions in which the plurality of emitter regions 17 are to be formed, and covers regions (plurality of gate embedded electrodes 13 and main surface insulating film 30) other than these regions. Next, an n-type impurity is introduced into the wafer 60 through the third mask 67. Hence, the plurality of emitter regions 17 are formed. Thereafter, the third mask 67 is removed.

Next, referring to FIG. 13I, a fourth mask 68 having a predetermined pattern is formed on the first wafer main surface 61. The fourth mask 68 exposes regions in which the plurality of in-base regions 20 are to be formed, and covers regions (plurality of gate embedded electrodes 13 and main surface insulating film 30) other than these regions.

Next, a p-type impurity is introduced into the wafer 60 through the fourth mask 68. Hence, the plurality of in-base regions 20 are formed. Thereafter, the fourth mask 68 is removed. The order of the formation step of the CS region 19 (see FIG. 13G), the formation step of the emitter region 17 (see FIG. 13H), and the formation step of the in-base region 20 (see FIG. 13I) is optional, and these steps may be appropriately replaced.

Next, referring to FIG. 13J, a fifth mask 69 having a predetermined pattern is formed on the first wafer main surface 61. With respect to the plurality of gate electrodes 35, the fifth mask 69 exposes a region in which the plurality of electrode recess portions 15 are to be formed, and covers a region in which the plurality of electrode projection portions 16 are to be formed. Next, an unnecessary portion of the gate electrode 35 is removed by an etching method through the fifth mask 69.

The etching method may be a wet etching method and/or a dry etching method. The unnecessary portion of the gate electrode 35 is removed until the electrode surface (etching surface) of the gate electrode 35 is placed closer to the bottom wall side of the gate trench 11 than the bottom portion of the plurality of emitter regions 17. Hence, the plurality of electrode recess portions 15 and the plurality of electrode projection portions 16 are formed in the upper end portion of the gate electrode 35. Thereafter, the fifth mask 69 is removed.

Next, referring to FIG. 13K, a second base insulating film 70 is formed on the first wafer main surface 61. The second base insulating film 70 serves as a base of the plurality of recess insulators 14 and as a base of the interlayer insulating film 31. The plurality of electrode recess portions 15 are refilled by the second base insulating film 70 with the plurality of gate insulating films 12 between the second base insulating film 70 and the electrode recess portion 15, and the second base insulating film 70 covers the first wafer main surface 61 as a film with the main surface insulating film 30 between the second base insulating film 70 and the first wafer main surface 61. A part, which is located inside the plurality of electrode recess portions 15, of the second base insulating films 70 is formed as the plurality of recess insulators 14, and a part, which covers the main surface insulating film 30, of the second base insulating films 70 is formed as the interlayer insulating film 31.

Next, referring to FIG. 13L, a sixth mask 71 having a predetermined pattern is formed on the second base insulating film 70 (interlayer insulating film 31). The sixth mask 71 exposes regions in which the plurality of connection holes 33 are to be formed, and covers regions other than these regions. Next, an unnecessary portion of the second base insulating film 70 (interlayer insulating film 31) is removed by an etching method through the sixth mask 71.

The etching method may be a wet etching method and/or a dry etching method. In this step, a part, which is exposed from the sixth mask 71, of the second base insulating films 70 (interlayer insulating film 31) and a part, which is exposed from the sixth mask 71, of the first base insulating films 64 (main-surface insulating film 30) are removed. Hence, the plurality of connection holes 33 are formed, and, simultaneously, the plurality of recess insulators 14 are formed. Thereafter, the sixth mask 71 is removed.

Next, referring to FIG. 13M, the plurality of chip recess portions 23 are formed to the first wafer main surface 61. The plurality of chip recess portions 23 are formed by further digging down a part, which is exposed from the plurality of connection holes 33, of the first wafer main surfaces 61 by an etching method. The etching method may be a wet etching method and/or a dry etching method that uses the interlayer insulating film 31 as a mask. As a matter of course, the plurality of chip recess portions 23 may be formed by an etching method through the sixth mask 71 mentioned above. In this case, the sixth aforementioned mask 71 is removed after the formation step of the plurality of chip recess portions 23.

Next, referring to FIG. 13N, a second base electrode film 72 is formed on the first wafer main surface 61. The second base electrode film 72 has a laminated structure including the first electrode film 43 and the second electrode film 44. The first electrode film 43 and the second electrode film 44 may be each formed by a sputtering method and/or a vapor deposition method.

Next, referring to FIG. 13O, a seventh mask 73 having a predetermined pattern is formed on the second base electrode film 72. The seventh mask 73 covers regions in which the gate electrode 35 and the emitter electrode 40 are to be formed, and exposes regions other than these regions. Next, an unnecessary portion of the second base electrode film 72 is removed by an etching method through the seventh mask 73. Hence, the gate electrode 35 and the emitter electrode 40 are formed. Thereafter, the seventh mask 73 is removed.

Next, referring to FIG. 13P, the wafer 60 is thinned until the wafer 60 reaches a predetermined thickness. This step may include a grinding method and/or an etching method with respect to the second wafer main surface 62. The grinding method may be a mechanical polishing method and/or a chemical-mechanical polishing method. The etching method may be a wet etching method and/or a dry etching method. The thinning step of the wafer 60 is not necessarily required to be performed, and may be excluded.

Next, referring to FIG. 13O, the n-type buffer region 7 is formed in a surficial portion of the second wafer main surface 62. The buffer region 7 may be formed by introducing an n-type impurity into the whole area of the surficial portion of the second wafer main surface 62. Also, the p-type collector region 8 is formed in the surficial portion of the second wafer main surface 62. The collector region 8 may be formed by injecting a p-type impurity into the whole area of the surficial portion of the second wafer main surface 62.

Next, referring to FIG. 13R, the collector electrode 45 is formed on the second wafer main surface 62. The collector electrode 45 may be formed by the sputtering method and/or the vapor deposition method. Thereafter, the wafer 60 is cut in the thickness direction, and the plurality of semiconductor devices 1A are cut out. The semiconductor device 1A is produced through a process including these steps.

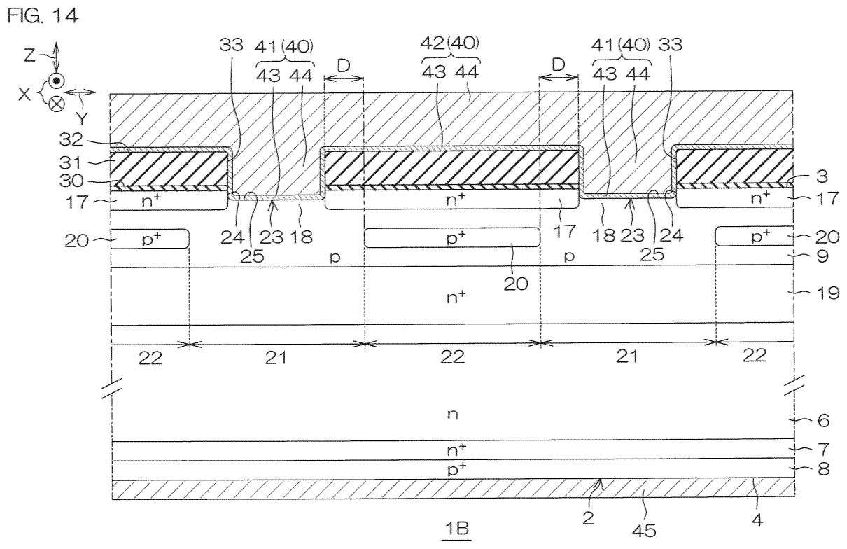

FIG. 14 is a cross-sectional view showing a semiconductor device 1B according to a second embodiment. The semiconductor device 1B has a form in which the design of the in-base region 20 has been changed in the semiconductor device 1A. Specifically, the in-base region 20 is formed in the base region 9 at a distance from the bottom portion of the emitter region 17, and faces the emitter region 17 across a part of the base region 9. In this embodiment, the in-base region 20 is formed at a distance from the bottom portion of the base region 9 toward the bottom side of the emitter region 17.

This in-base region 20 is formed by adjusting a place at which a p-type impurity is introduced in the formation step of the in-base region 20 mentioned above (see FIG. 13I). As described above, the same effect as the effect according to the semiconductor device 1A is fulfilled also by the semiconductor device 1B.

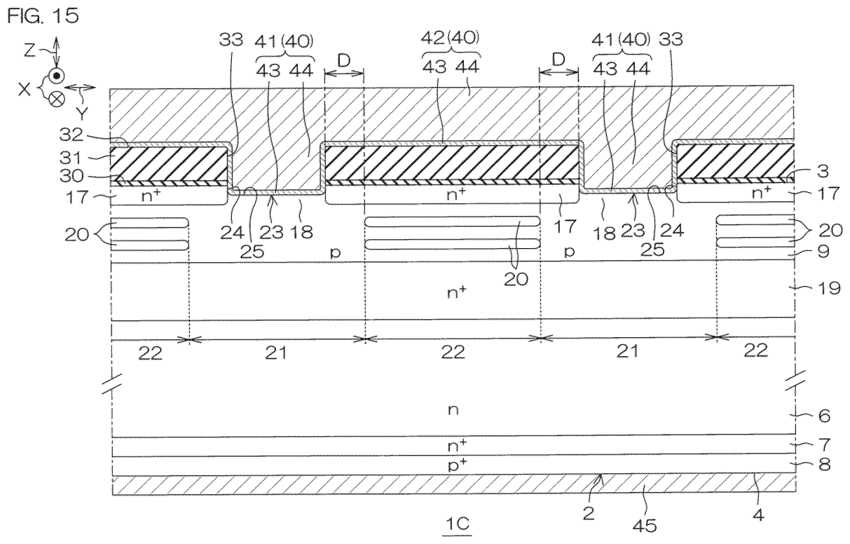

FIG. 15 is a cross-sectional view showing a semiconductor device 1C according to a third embodiment. The semiconductor device 1C has a form in which the design of the in-base region 20 has been changed in the semiconductor device 1A. Specifically, in the semiconductor device 1C, the plurality of in-base regions 20 are arranged at a distance from each other in the thickness direction of the chip 2 in a region directly under each of the emitter regions 17.

In this embodiment, the plurality of in-base regions 20 are formed at a distance from the bottom portion of the base region 9 and from the bottom portion of the emitter region 17. The plurality of in-base regions 20 may each have a thickness equal to each other, or may each have a thickness differing from each other. The plurality of in-base regions 20 may be arranged at equal intervals in the thickness direction of the chip 2, or may be arranged at mutually different intervals in the thickness direction of the chip 2.

As a matter of course, the in-base region 20 adjacent to the emitter region 17 may be connected to the emitter region 17. Also, the in-base region 20 adjacent to the bottom portion of the base region 9 may cross the bottom portion of the base region 9. In this case, the in-base region 20 may be connected to the CS region 19. In a case in which the CS region 19 does not exist, the in-base region 20 may be connected to the drift region 6.

These plurality of in-base regions 20 are formed by adjusting a place at which a p-type impurity is introduced and by adjusting the introducing frequency of the p-type impurity in the formation step of the in-base region 20 mentioned above (see FIG. 13I). As described above, the same effect as the effect according to the semiconductor device 1A is fulfilled also by the semiconductor device 1C.

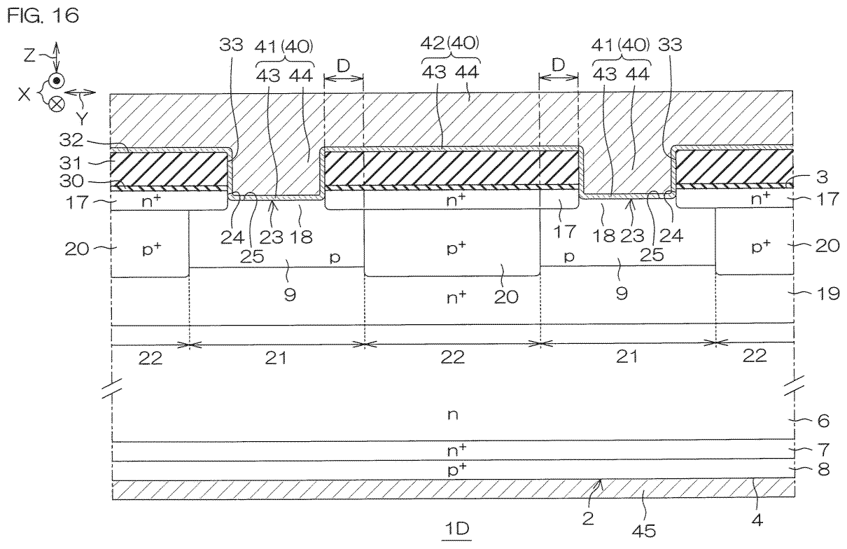

FIG. 16 is a cross-sectional view showing a semiconductor device 1D according to a fourth embodiment. The semiconductor device 1D has a form in which the design of the in-base region 20 has been changed in the semiconductor device 1A. In this embodiment, the in-base region 20 is formed in the whole area of the thickness range between the bottom portion of the base region 9 and the bottom portion of the emitter region 17 in a region between the bottom portion of the base region 9 and the bottom portion of the emitter region 17.

That is, the in-base region 20 has an upper end portion connected to the emitter region 17 and a lower end portion that crosses the bottom portion of the base region 9. In this embodiment, the lower end portion of the in-base region 20 is connected to the CS region 19. In a case in which the CS region 19 does not exist, the lower end portion of the in-base region 20 may be connected to the drift region 6.

This in-base region 20 is formed by adjusting a place at which a p-type impurity is introduced or by adjusting the introducing frequency of the p-type impurity in the formation step of the in-base region 20 mentioned above (see FIG. 13I). As described above, the same effect as the effect according to the semiconductor device 1A is fulfilled also by the semiconductor device 1D.

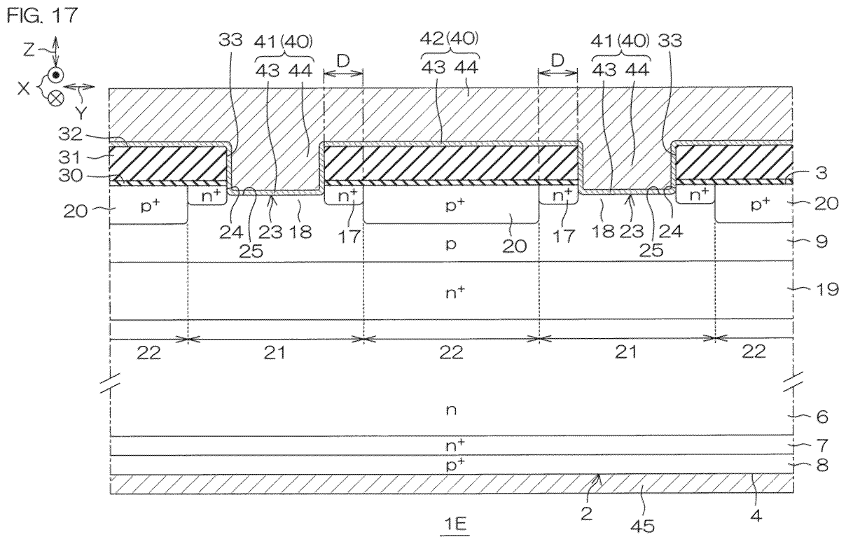

FIG. 17 is a cross-sectional view showing a semiconductor device 1E according to a fifth embodiment. The semiconductor device 1E has a form in which the design of the in-base region 20 has been changed in the semiconductor device 1A. Specifically, the in-base region 20 is formed so as to be exposed from the first main surface 3. The in-base region 20 may be formed so as to penetrate an inward portion of the emitter region 17, or may be formed in a region between the plurality of emitter regions 17. The in-base region 20 has a bottom portion that is thick than the emitter region 17 and that is placed closer to the bottom side of the base region 9 than the bottom portion of the emitter region 17.

This in-base region 20 is formed by adjusting a place at which a p-type impurity is introduced in the formation step of the in-base region 20 mentioned above (see FIG. 13I). As described above, the same effect as the effect according to the semiconductor device 1A is fulfilled also by the semiconductor device 1E.

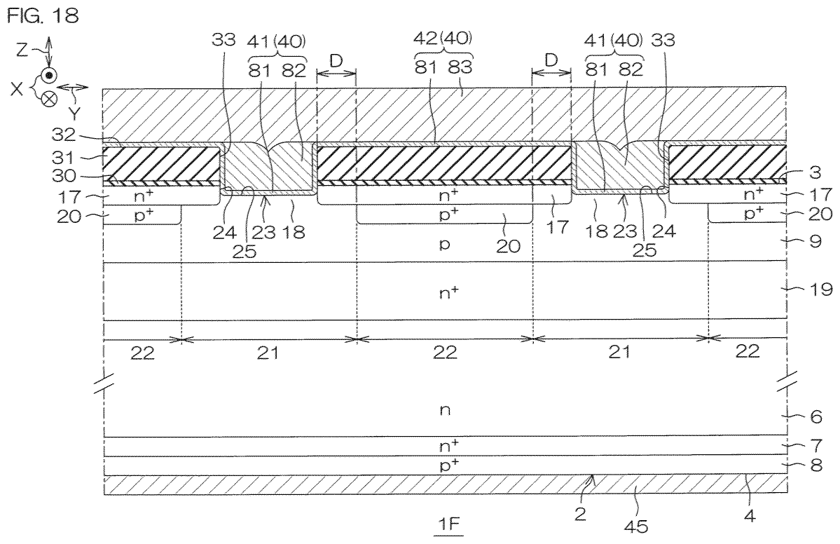

FIG. 18 is a cross-sectional view showing a semiconductor device 1F according to a sixth embodiment. The semiconductor device 1F has a form in which the design of the emitter electrode 40 has been changed in the semiconductor device 1A. In this embodiment, the emitter electrode 40 has a laminated structure including a first electrode film 81, a plurality of second electrode films 82, and a third electrode film 83 that are laminated in that order from the chip 2 side.

The first electrode film 81 is formed as a film along the insulating main surface 32 of the interlayer insulating film 31 and along the wall surface of the plurality of connection holes 33. The first electrode film 81 covers the plurality of recess insulators 14 as a film, the wall surface of the plurality of chip recess portions 23, and the wall surface of the plurality of connection holes 33 inside the plurality of connection holes 33. The first electrode film 81 may include a Ti-based metal film. The first electrode film 81 may have a single-layer structure consisting of a Ti film or a TiN film. The first electrode film 81 may have a laminated structure including a Ti film and a TiN film that are laminated in an arbitrary order.

The plurality of second electrode films 82 are embedded in the plurality of connection holes 33, respectively, with the first electrode film 81 between the second electrode film 82 and the plurality of connection holes 33. The plurality of second electrode films 82 cover the plurality of recess insulators 14, the wall surface of the plurality of chip recess portions 23, and the wall surface of the plurality of connection holes 33 across the first electrode film 81 inside the plurality of connection holes 33. The plurality of second electrode films 82 may include at least one among a W (tungsten) film, an Mo (molybdenum) film, an Ni (nickel) film, a pure Al film, a pure Cu film, an Al alloy film, and a Cu alloy film. Preferably, the plurality of second electrode films 82 include a W film.

The third electrode film 83 is formed as a film on the interlayer insulating film 31 so as to cover the first electrode film 81 and the plurality of second electrode films 82. The third electrode film 83 may include an Al-based metal film or a Cu-based metal film. The Al-based metal film may include at least one among a pure Al film, an AlCu alloy film, an AlSi alloy film, and an AlSiCu alloy film. The Cu-based metal film may be a pure Cu film or a Cu alloy film. The AlCu alloy film and the AlSiCu alloy film are an example of the Cu alloy film.

As thus described, the plurality of emitter connection electrodes 41 are formed by a laminated film consisting of the first electrode film 81 and the second electrode film 82, and the emitter terminal electrode 42 is formed by a laminated film consisting of the first electrode film 81 and the third electrode film 83 in the emitter electrode 40 according to the sixth embodiment. That is, the emitter terminal electrode 42 is formed structurally independently of the plurality of emitter connection electrodes 41.

The first electrode film 81 is not necessarily required to cover the insulating main surface 32 of the interlayer insulating film 31, and may expose the insulating main surface 32. In this case, the emitter terminal electrode 42 is formed by a monolayer film of the third electrode film 83. As described above, the same effect as the effect according to the semiconductor device 1A is fulfilled also by the semiconductor device 1F. The emitter electrode 40 according to the sixth embodiment is applicable also to the second to fifth embodiments.

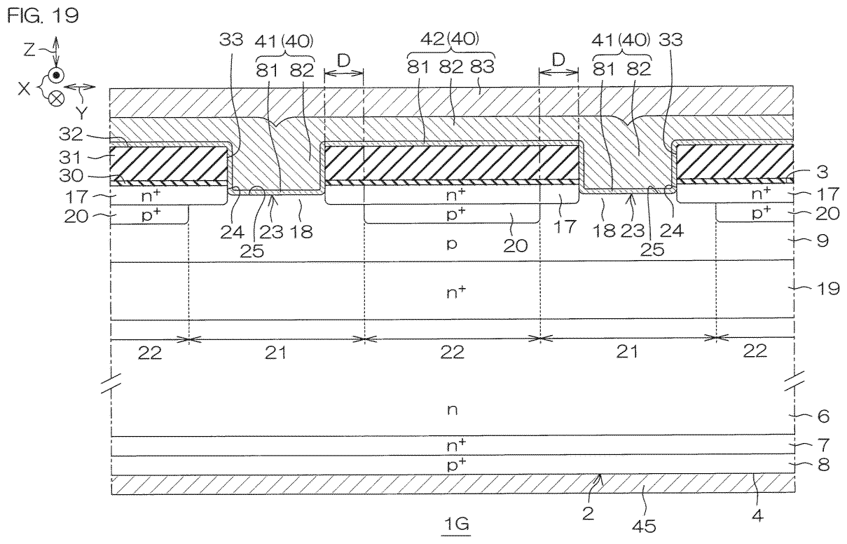

FIG. 19 is a cross-sectional view showing a semiconductor device 1G according to a seventh embodiment. The semiconductor device 1G has a form in which the design of the second electrode film 82 has been changed in the semiconductor device 1F according to the sixth embodiment. Specifically, the second electrode film 82 is embedded in the plurality of connection holes 33 (chip recess portion 23) with the first electrode film 81 between the second electrode film 82 and the connection hole 33, and covers the insulating main surface 32 with the first electrode film 81 between the second electrode film 82 and the insulating main surface 32. The second electrode film 82 covers the plurality of recess insulators 14, the wall surface of the plurality of chip recess portions 23, and the wall surface of the plurality of connection holes 33 inside the plurality of connection holes 33. In this embodiment, the third electrode film 83 mentioned above is formed as a film on the second electrode film 82.

As thus described, the plurality of emitter connection electrodes 41 are formed by a laminated film consisting of the first electrode film 81 and the second electrode film 82, and the emitter terminal electrode 42 is formed by a laminated film consisting of the first electrode film 81, the second electrode film 82, and the third electrode film 83 in the emitter electrode 40 according to the seventh embodiment. That is, the emitter terminal electrode 42 is formed structurally independently of the plurality of emitter connection electrodes 41. As described above, the same effect as the effect according to the semiconductor device 1A is fulfilled also by the semiconductor device 1G. The emitter electrode 40 according to the seventh embodiment is applicable also to the second to fifth embodiments.

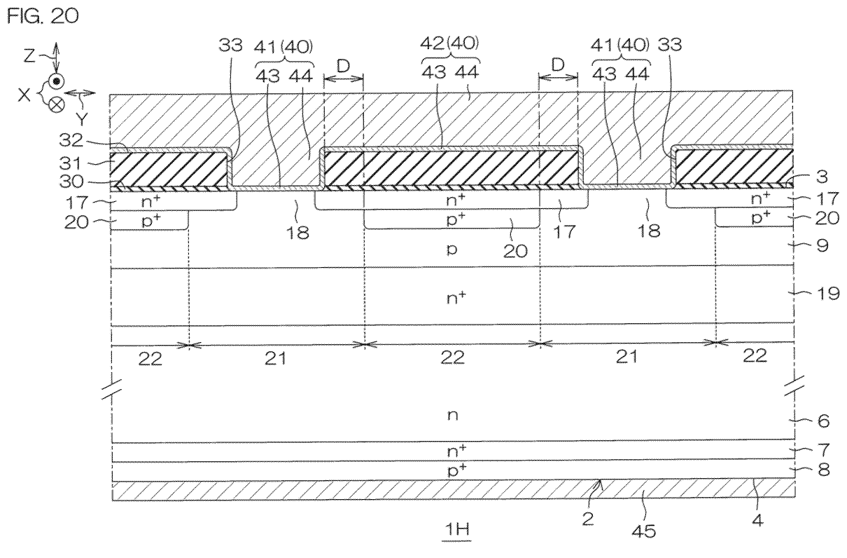

FIG. 20 is a cross-sectional view showing a semiconductor device 1H according to an eighth embodiment. The semiconductor device 1H has a form in which the chip recess portion 23 has been removed in the semiconductor device 1A. In this case, the plurality of connection holes 33 are formed in the interlayer insulating film 31 so as to expose a region (i.e., base intermediate region 18) between the plurality of emitter regions 17 adjoining each other and the edge portion of the plurality of emitter regions 17.

Each of the emitter connection electrodes 41 mentioned above is electrically connected to the plurality of emitter regions 17 and to the base intermediate region 18 inside each of the connection holes 33. As described above, the same effect as the effect according to the semiconductor device 1A is fulfilled also by the semiconductor device 1H. The form in which the chip recess portion 23 has been removed is applicable also to the second to seventh embodiments.

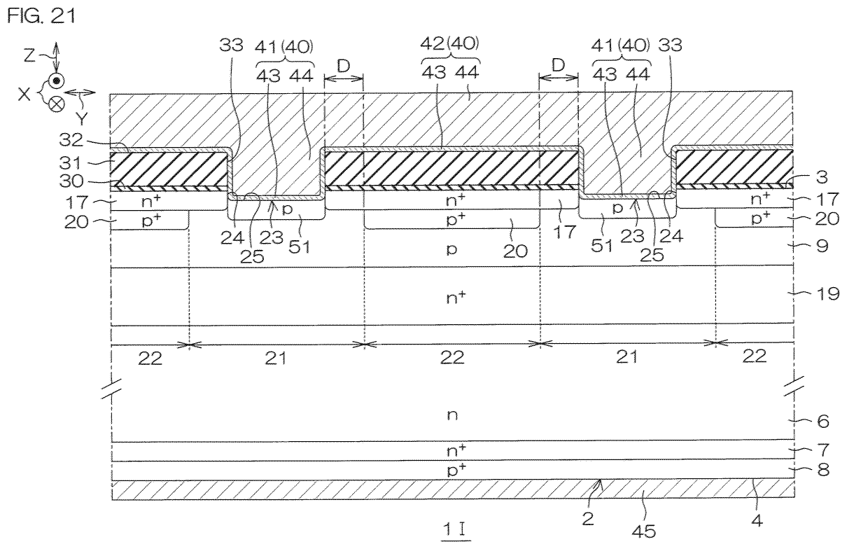

FIG. 21 is a cross-sectional view showing a semiconductor device 1I according to a ninth embodiment. The semiconductor device 1I has a form in which at least one (in this embodiment, a plurality of) intermediate in-base region 51 (see also FIG. 11) has been added in the semiconductor device 1A. The plurality of intermediate in-base regions 51 are each formed in a region (i.e., base intermediate region 18) between the plurality of emitter regions 17 in the surficial portion of the base region 9.

Specifically, the plurality of intermediate in-base regions 51 are formed in a region along the bottom wall of the chip recess portion 23 at a distance from the plurality of in-base regions 20 in the surface direction of the first main surface 3 (specifically, in the second direction Y) in a plan view and in a cross-sectional view. That is, the plurality of intermediate in-base regions 51 are formed so as to expose the bottom portion of the plurality of emitter regions 17 between the plurality of in-base regions 20.

The plurality of intermediate in-base regions 51 may each have a bottom portion placed closer to the bottom side of the base region 9 than the bottom portion of the plurality of emitter regions 17. The bottom portion of the plurality of intermediate in-base regions 51 may be located on the first main surface 3 side with respect to the bottom portion of the plurality of base regions 9. Preferably, the plurality of intermediate in-base regions 51 have a p-type impurity concentration higher than the base region 9. Particularly preferably, the p-type impurity concentration of the plurality of intermediate in-base regions 51 is lower than the plurality of in-base regions 20.

This intermediate in-base region 51 is formed by adding a step of introducing a p-type impurity into the recess bottom wall 25 of the chip recess portion 23 after the formation step of the chip recess portion 23 (FIG. 13M). Each of the emitter connection electrodes 41 mentioned above is electrically connected to the intermediate in-base region 51 and to the plurality of emitter regions 17 inside each of the connection holes 33. As described above, the same effect as the effect according to the semiconductor device 1A is fulfilled also by the semiconductor device 1I. The form including the intermediate in-base region 51 is applicable also to the second to eighth embodiments.

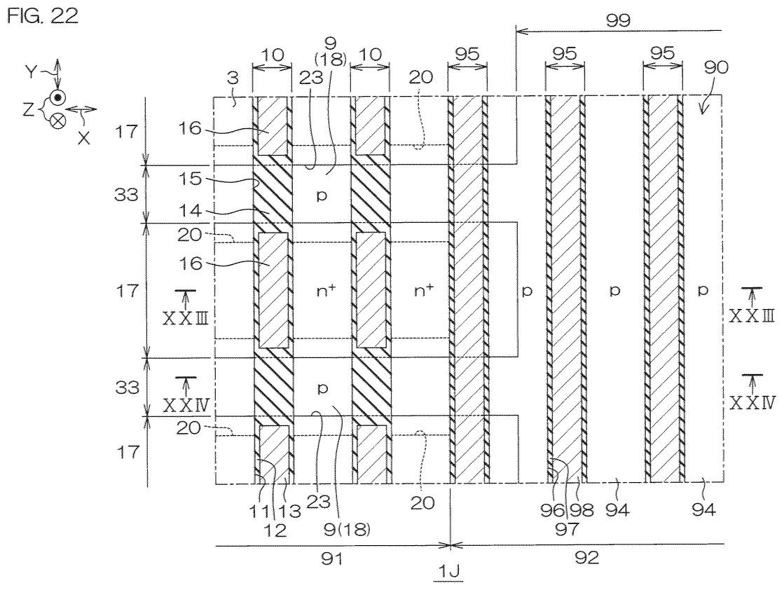

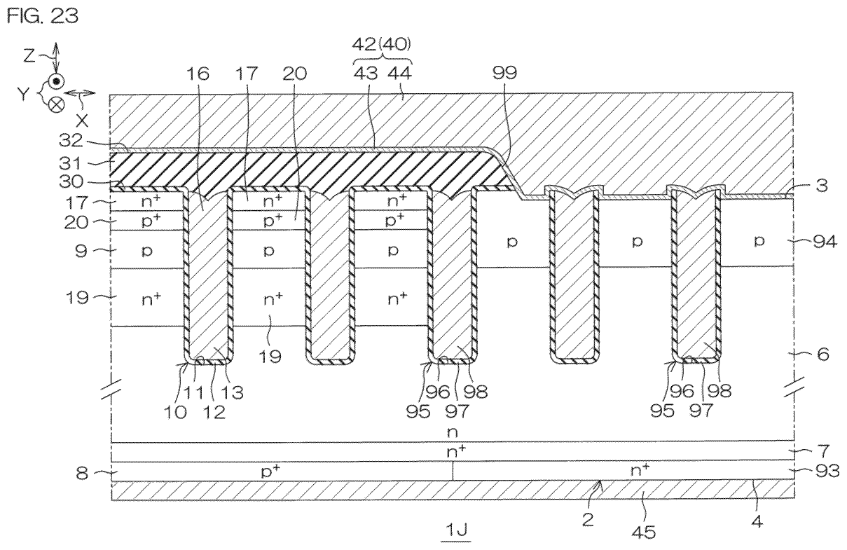

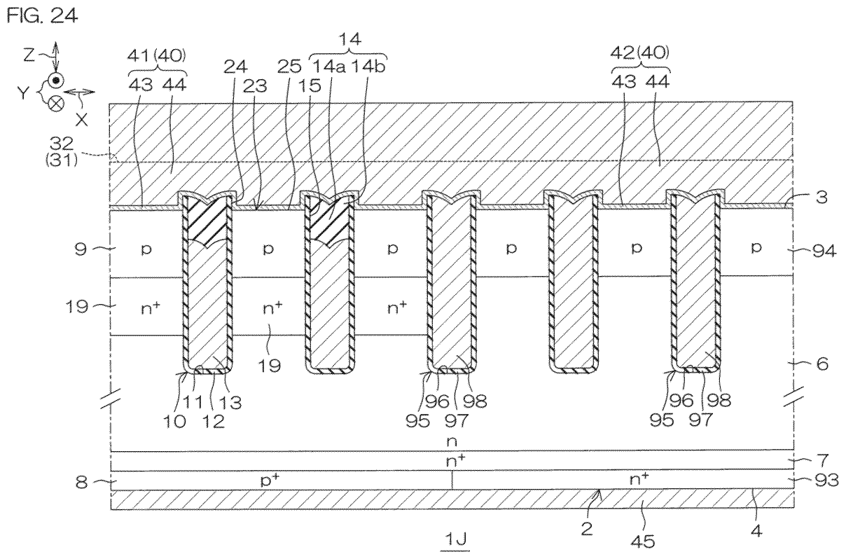

FIG. 22 is a plan view showing a main portion of a semiconductor device 1J according to a tenth embodiment. FIG. 23 is a cross-sectional view along line XXIII-XXIII shown in FIG. 22. FIG. 24 is a cross-sectional view along line XXIV-XXIV shown in FIG. 22. Referring to FIG. 22 to FIG. 24, the semiconductor device 1J is an RC-IGBT semiconductor device (semiconductor switching device) having RC-IGBT (Reverse Conducting-IGBT) that integrally includes IGBT and a diode. The diode is a reflux diode with respect to IGBT.

The semiconductor device 1J includes at least one (in this embodiment, a plurality of) RC-IGBT region 90 formed in the first main surface 3. The plurality of RC-IGBT regions 90 are formed at an inward portion of the first main surface 3 at a distance from a peripheral edge of the first main surface 3 in a plan view. In this embodiment, the plurality of RC-IGBT regions 90 are each formed in a belt shape extending in the first direction X, and are arrayed at a distance from each other in the second direction Y. That is, the plurality of RC-IGBT regions 90 are arrayed in a stripe shape extending in the first direction X in a plan view. The plurality of RC-IGBT regions 90 each have a first end portion on one side (third side surface 5C side) and a second end portion on the other side (fourth side surface 5D side).

The plurality of RC-IGBT regions 90 each include at least one (in this embodiment, a plurality of) IGBT region 91 and at least one (in this embodiment, a plurality of) diode region 92. The plurality of IGBT regions 91 are each formed in a quadrangular shape in a plan view. The plurality of diode regions 92 are each formed in a quadrangular shape in a plan view. The plurality of IGBT regions 91 are arrayed at a distance from each other in the first direction X in each of the RC-IGBT regions 90. The plurality of diode regions 92 are respectively arrayed in regions differing from the plurality of IGBT regions 91 in each of the RC-IGBT regions 90.

Specifically, the plurality of diode regions 92 are each arrayed so as to adjoin at least one IGBT region 91. In this embodiment, the plurality of diode regions 92 are arrayed alternately with the plurality of IGBT regions 91 along the first direction X. The first and second end portions of each of the RC-IGBT regions 90 are each formed by the IGBT region 91 or the diode region 92.

The plurality of IGBT regions 91 according to one of the RC-IGBT regions 90 may face the plurality of IGBT regions 91 according to the other RC-IGBT region 90 in the second direction Y. Likewise, the plurality of diode regions 92 according to one of the RC-IGBT regions 90 may face the plurality of diode regions 92 according to the other RC-IGBT region 90 in the second direction Y. That is, the plurality of IGBT regions 91 may be arrayed in a matrix manner at a distance from each other in the first and second directions X and Y in a plan view. Also, the plurality of diode regions 92 may be arrayed in a matrix manner at a distance from each other in the first and second directions X and Y in a plan view.

The plurality of IGBT regions 91 according to one of the RC-IGBT regions 90 may face the plurality of diode regions 92 according to the other RC-IGBT region 90 in the second direction Y. Likewise, the plurality of diode regions 92 according to one of the RC-IGBT regions 90 may face the plurality of IGBT regions 91 according to the other RC-IGBT region 90 in the second direction Y. That is, the plurality of IGBT regions 91 may be arrayed in a staggered manner at a distance from each other in the first and second directions X and Y in a plan view. Also, the plurality of diode regions 92 may be arrayed in a staggered manner at a distance from each other in the first and second directions X and Y in a plan view.

The plane area of each of the diode regions 92 may be substantially equal to the plane area of each of the IGBT regions 91, or may be different from the plane area of each of the IGBT regions 91. The plane area of each of the diode regions 92 may be more than the plane area of each of the IGBT regions 91, or may be less than plane area of each of the IGBT regions 91. Preferably, the plane area of each of the diode regions 92 is less than the plane area of each of the IGBT regions 91. That is, preferably, the total plane area of the plurality of diode regions 92 is less than the total plane area of the plurality of IGBT regions 91.

The semiconductor device 1J includes the drift region 6, the buffer region 7, and the collector region 8 inside the chip 2. With respect to the drift region 6, the buffer region 7, and the collector region 8, a description of these regions according to the first embodiment is applied, and this description is omitted. The semiconductor device 1J includes the base region 9, the plurality of trench gate structures 10, the plurality of emitter regions 17, the plurality of CS regions 19, the plurality of chip recess portions 23, the plurality of in-base regions 20, the main surface insulating film 30, the interlayer insulating film 31 (plurality of connection holes 33), and the emitter electrode 40 in each of the IGBT regions 91. With respect to each of the structures in each of the IGBT regions 91, a description of each of the structures according to the first embodiment is applied, and this description is omitted.

The semiconductor device 1J includes an n-type cathode region 93 formed in the surficial portion of the second main surface 4 in each of the diode regions 92. The cathode region 93 may be referred to as a “first polar region.” In this embodiment, the cathode region 93 is formed in a layer shape extending along the second main surface 4 in a part of the second main surface 4 (part located in the diode region 92).

The cathode region 93 penetrates the collector region 8 so as to be connected to the buffer region 7. The cathode region 93 is a region that has an n-type impurity concentration exceeding the p-type impurity concentration of the collector region 8 and in which the conductivity type of a part of the collector region 8 is replaced from the p-type to the n-type. Preferably, the cathode region 93 has an n-type impurity concentration higher than the drift region 6 (buffer region 7).

The semiconductor device 1J includes a p-type anode region 94 formed in the surficial portion of the first main surface 3 in each of the diode regions 92. The anode region 94 may be referred to as a “second polar region.” The anode region 94 is formed in a layer shape extending along the first main surface 3 in each of the diode regions 92, and faces the cathode region 93 in the thickness direction of the chip 2. In this embodiment, the whole area of the anode region 94 faces at least one part of the cathode region 93.

As a matter of course, the anode region 94 may face a part of the collector region 8 and a part of the cathode region 93 in the thickness direction of the chip 2. The anode region 94 is formed so as to be shallower than the plurality of trench gate structures 10 with respect to the thickness direction of the chip 2. Specifically, the anode region 94 is formed so as to be shallower than the intermediate portion of the plurality of trench gate structures 10 with respect to the thickness direction of the chip 2. The anode region 94 may have a depth substantially equal to that of the base region 9. As a matter of course, the anode region 94 may be formed so as to be deeper than the base region 9 with respect to the thickness direction of the chip 2.

The anode region 94 makes a pn junction with the drift region 6. Hence, a pn junction diode in which the anode region 94 is set as an anode and in which the cathode region 93 (drift region 6) is set as a cathode is formed. The anode region 94 may have a p-type impurity concentration substantially equal to that of the base region 9. As a matter of course, the p-type impurity concentration of the anode region 94 may be higher than the p-type impurity concentration of the base region 9, or may be lower than the p-type impurity concentration of the base region 9.

The semiconductor device 1J includes a plurality of anode trench structures 95 formed in the first main surface 3 in each of the diode regions 92. A potential (in this embodiment, anode potential) differing from the gate potential is given to the anode trench structure 95. In this embodiment, the anode potential is an emitter potential. The anode trench structure 95 may be referred to as an “emitter trench structure.”

The plurality of anode trench structures 95 penetrate the anode region 94 so as to reach the drift region 6 in a cross-sectional view. The plurality of anode trench structures 95 are arrayed at a distance from each other in the first direction X in a plan view, and are each formed in a belt shape extending in the second direction Y. That is, the plurality of anode trench structures 95 are arrayed in a stripe shape extending in the second direction Y.

The plurality of anode trench structures 95 may each have a width of not less than 0.5 μm and not more than 3 μm. Preferably, the width of each of the anode trench structures 95 is substantially equal to the width of each of the trench gate structures 10. The plurality of anode trench structures 95 may each have a depth of not less than 1 μm and not more than 10 μm. Preferably, the depth of each of the anode trench structures 95 is substantially equal to the depth of each of the trench gate structures 10.

The distance (trench pitch) in the first direction X between the plurality of anode trench structures 95 may be not less than 0.1 μm and not more than 1 μm. Preferably, the distance between the plurality of anode trench structures 95 is 0.5 μm or less. Preferably, the distance (trench pitch) in the first direction X between the plurality of anode trench structures 95 is substantially equal to the distance (trench pitch) in the first direction X between the plurality of trench gate structures 10.

A configuration of the single anode trench structure 95 will be hereinafter described. The anode trench structure 95 includes an anode trench 96, an anode insulating film 97, and an anode embedded electrode 98. The anode trench 96 is dug down from the first main surface 3 toward the second main surface 4, and defines a wall surface of the anode trench structure 95.

The anode trench 96 extends in a direction perpendicular to the first main surface 3. The anode trench 96 may be formed in a tapered shape in which the width of its opening becomes narrower from the opening toward its bottom wall. Preferably, a bottom wall of the anode trench 96 is formed in a curved shape toward the second main surface 4. As a matter of course, the bottom wall of the anode trench 96 may be formed in parallel with the first main surface 3. In this case, preferably, a corner portion of the bottom wall of the anode trench 96 is formed in a curved shape.

The anode insulating film 97 covers the wall surface of the anode trench 96 as a film, and defines a recessed space inside the anode trench 96. The anode insulating film 97 may include at least one among a silicon oxide film, a silicon nitride film, a silicon oxynitride film, and an aluminum oxide film. Preferably, the anode insulating film 97 includes a silicon oxide film made of an oxide of the chip 2. Preferably, the anode insulating film 97 includes the same insulation material s the gate insulating film 12.

The anode embedded electrode 98 is embedded in the anode trench 96 with the anode insulating film 97 between the anode embedded electrode 98 and the anode trench 96. An anode potential 1 (in this embodiment, emitter potential) is given to the anode embedded electrode 98. The anode embedded electrode 98 may include conductive polysilicon. The anode embedded electrode 98 faces the anode region 94 and the drift region 6 across the anode insulating film 97. The anode embedded electrode 98 may have an upper end portion that protrudes higher than the first main surface 3. The upper end portion of the anode embedded electrode 98 may have a hollow toward the bottom wall of the anode trench 96.

The interlayer insulating film 31 mentioned above includes a diode opening 99 that exposes the anode region 94 and the plurality of anode trench structures 95 in each of the diode regions 92. The diode opening 99 exposes the inward portion of the anode region 94 and the inward portion of the plurality of anode trench structures 95. Preferably, the diode opening 99 exposes all of the anode trench structures 95.

A wall surface of the diode opening 99 has an inclined surface that makes an acute angle with the first main surface 3. The inclined surface may be formed in a linear shape, in a concave curved shape toward the first main surface 3, or in a convex curved shape receding from the first main surface 3 in a cross-sectional view. The inclination angle of an opening wall surface may be not less than 30° and less than 90°. Preferably, the inclination angle exceeds 45°. Particularly preferably, the inclination angle is 60° or more.

The inclination angle is an angle between the first main surface 3 and the inclined surface inside the interlayer insulating film 31. Specifically, the inclination angle is an angle made between a straight line, which connects a starting point and an ending point of the inclined surface, and the first main surface 3. As a matter of course, a wall surface that defines each of the diode openings 99 may be formed so as to be perpendicular to the first main surface 3 (i.e., inclination angle=) 90°.

The emitter terminal electrode 42 (emitter electrode 40) mentioned above enters the inside of the diode opening 99 from above the interlayer insulating film 31, and is electrically connected to the anode region 94 and to the plurality of anode trench structures 95 inside this diode opening 99. The collector electrode 45 mentioned above is electrically connected to the collector region 8 and the cathode region 93 exposed from the second main surface 4. The collector electrode 45 makes an ohmic contact with the collector region 8 and the cathode region 93.

As described above, the same effect as the effect according to the semiconductor device 1A is fulfilled also by the semiconductor device 1J. The structure including the RC-IGBT region 90 (diode region 92) is applicable also to the second to ninth embodiments.

Each of the aforementioned embodiments can be carried out in still other modes. In the aforementioned embodiment, an example in which the chip 2 is made of a silicon monocrystal substrate was shown. However, the chip 2 may be made of an SiC (silicon carbide) monocrystal substrate. In the aforementioned embodiment, the n-type semiconductor region may be replaced by the p-type semiconductor region, and the p-type semiconductor region may be replaced by the n-type semiconductor region. A concrete configuration in this case can be obtained by replacing the “n-type” with the “p-type” and, simultaneously, replacing the “p-type” with the “n-type” in the description given above and in the accompanying drawings.

The first and second directions X and Y are determined by the extending direction of the first to fourth side surfaces 5A to 5D as described in the aforementioned embodiment. However, the first and second directions X and Y may be arbitrary directions as long as the relationship of intersecting each other (specifically, perpendicularly intersecting each other) is maintained. For example, the first direction X may be a direction intersecting the first to fourth side surfaces 5A to 5D, and the second direction Y may be a direction intersecting the first to fourth side surfaces 5A to 5D.

Characteristic examples extracted from this description and from the drawings are hereinafter shown. Hereinafter, alphanumeric characters etc., in parentheses represent corresponding components in the aforementioned embodiments, and yet this representation does not denote that the scope of each clause is limited to the embodiment. The “semiconductor device” according to the following clauses may be replaced by a “semiconductor switching device,” an “IGBT semiconductor device,” or an “RC-IGBT semiconductor device.”

[A1] A semiconductor device (1A to 1J) comprising; a chip (2) that has a main surface (3); a first conductivity type (p-type) base region (9) that is formed in a surficial portion of the principal surface (3); a trench gate structure (10) that is formed in the main surface (3) so as to penetrate the base region (9); a second conductivity type (n-type) emitter region (17) that is formed in a region along the trench gate structure (10) in surficial portion of the base region (9); a first conductivity type (p-type) in-base region (20) that is formed in a region between a bottom portion of the base region (9) and a bottom portion of the emitter region (17) in the base region (9) and that has an impurity concentration higher than the base region (9); an insulating film (31) that covers the main surface (3) and that has a connection hole (33) that exposes a part of the emitter region (17) at a distance from the in-base region (20) in a direction along the main surface (3); and a connection electrode (41) that is arranged in the connection hole (33) so as to be electrically connected to the base region (9) and to the emitter region (17).

[A2] The semiconductor device (1A to 1J) according to A1, wherein the in-base region (20) is formed narrower than the emitter region (17).

[A3] The semiconductor device (1A to 1J) according to A1 or A2, wherein the connection hole (33) intersects the trench gate structure (10) in a plan view, and the connection electrode (41) intersects the trench gate structure (10) in a plan view.

[A4] The semiconductor device (1A to 1J) according to any one of A1 to A3, further comprising: a recess portion (23) that is formed in the main surface (3) so as to expose the emitter region (17); wherein the connection hole (33) communicates with the recess portion (23), and the connection electrode (41) includes a portion located in the connection hole (33) and a portion located in the recess portion (23).

[A5] The semiconductor device (1A to 1J) according to A4, wherein the recess portion (23) has a bottom wall placed closer to a side of the main surface (3) than the bottom portion of the base region (9).

[A6] The semiconductor device (1A to 1J) according to A5, wherein a bottom wall of the recess portion (23) is placed closer to the side of the main surface (3) than the bottom portion of the emitter region (17).

[A7] The semiconductor device (1A to 1J) according to any one of A1 to A6 wherein the in-base region (20) is connected to the emitter region (17).

[A8] The semiconductor device (1A to 1J) according to any one of A1 to A6, wherein the in-base region (20) is formed at a distance from the emitter region (17) toward a side of the bottom of the base region (9).

[A9] The semiconductor device (1A to 1J) according to any one of A1 to A6, wherein the in-base regions (20) are formed at a distance from each other in a thickness direction of the chip (2).

[A10] The semiconductor device (1A to 1J) according to any one of A1 to A6, wherein the in-base region (20) is formed in a whole area of a thickness range between the bottom portion of the base region (9) and the bottom portion of the emitter region (17).

[A11] The semiconductor device (1A to 1J) according to any one of A1 to A10, further comprising: a first conductivity type (p-type) second in-base region (51) that is formed in the base region (9) so as to be exposed from the connection hole (33) and that has an impurity concentration higher than the base region (9), wherein the connection electrode (41) is electrically connected to the second in-base region (51) in the connection hole (33).

[A12] The semiconductor device (1A to 1J) according to A11, wherein the second in-base region (51) is formed at a distance from the in-base region (20).

[A13] The semiconductor device (1A to 1J) according to any one of A1 to A12, wherein the trench gate structure (10) includes a trench (11) formed in the main surface (3), a gate insulating film (12) covering a wall surface of the trench (11), a gate embedded electrode (13) embedded in the trench (11) with the gate insulating film (12) between the gate embedded electrode (13) and the trench (11), an electrode recess portion (15) formed at an electrode surface of the gate embedded electrode (13), and a recess insulator (14) covering the electrode recess portion (15), and the insulating film (31) covers the gate embedded electrode (13), and has the connection hole (33) that exposes the recess insulator (14), and the connection electrode (41) has a portion facing the gate embedded electrode (13) across the recess insulator (14) in the connection hole (33).

[A14] The semiconductor device (1A to 1J) according to A13, wherein the in-base region (20) is formed at a distance from the recess insulator (14).

[A15] The semiconductor device (1A to 1J) according to A13 or A14, wherein the connection hole (33) exposes the emitter region (17) and the recess insulator (14).

[A16] The semiconductor device (1A to 1J) according to any one of A13 to A15, wherein the recess insulator (14) has a portion that faces the base region (9) along a surface direction of the main surface.

[A17] The semiconductor device (1A to 1J) according to any one of A13 to A16, wherein the recess insulator (14) has an embedded portion (14a) placed closer to a side of a bottom wall of the trench (11) than the main surface (3) and a projection portion (14b) placed higher than the main surface (3) in a cross-sectional view.

[A18] The semiconductor device (1A to 1J) according to any one of A13 to A17, wherein the insulating film (31) has an insulating main surface (32) placed higher than an upper end portion of the recess insulator (14).

[A19] The semiconductor device (1A to 1J) according to any one of A1 to A18, further comprising: a terminal electrode (42) that is formed integrally with the connection electrode (41) and that covers the insulating film (31).

[A20] The semiconductor device (1A to 1J) according to any one of A1 to A18, further comprising: a terminal electrode (42) that is formed structurally independently of the connection electrode (41) and that covers the insulating film (31) and the connection electrode (41).

Although the embodiments have been described in detail as above, these are merely concrete examples used to clarify the technical contents. Various technical ideas extracted from this description can be appropriately combined together without being limited to the explanatory order, the order of the embodiments, or the like in the description.

What is claimed is:

1. A semiconductor device comprising:
a chip that has a main surface;
a first conductivity type base region that is formed in a surficial portion of the principal surface;
a trench gate structure that is formed in the main surface so as to penetrate the base region;
a second conductivity type emitter region that is formed in a region along the trench gate structure in a surficial portion of the base region;
a first conductivity type in-base region that is formed in a region between a bottom portion of the base region and a bottom portion of the emitter region in the base region and that has an impurity concentration higher than the base region;
an insulating film that covers the main surface and that has a connection hole that exposes a part of the emitter region at a distance from the in-base region in a direction along the main surface; and
a connection electrode that is arranged in the connection hole so as to be electrically connected to the base region and to the emitter region.

2. The semiconductor device according to claim 1,
wherein the in-base region is formed narrower than the emitter region.

3. The semiconductor device according to claim 1,
wherein the connection hole intersects the trench gate structure in a plan view, and
the connection electrode intersects the trench gate structure in a plan view.

4. The semiconductor device according to claim 1, further comprising:
a recess portion that is formed in the main surface so as to expose the emitter region;
wherein the connection hole communicates with the recess portion, and
the connection electrode includes a portion located in the connection hole and a portion located in the recess portion.

5. The semiconductor device according to claim 4,
wherein the recess portion has a bottom wall placed closer to a side of the main surface than the bottom portion of the base region.

6. The semiconductor device according to claim 5,
wherein a bottom wall of the recess portion is placed closer to the side of the main surface than the bottom portion of the emitter region.

7. The semiconductor device according to claim 1,
wherein the in-base region is connected to the emitter region.

8. The semiconductor device according to claim 1,
wherein the in-base region is formed at a distance from the emitter region toward a side of the bottom of the base region.

9. The semiconductor device according to claim 1,
wherein the in-base regions are formed at a distance from each other in a thickness direction of the chip.

10. The semiconductor device according to claim 1,
wherein the in-base region is formed in a whole area of a thickness range between the bottom portion of the base region and the bottom portion of the emitter region.

11. The semiconductor device according to claim 1, further comprising:
a first conductivity type second in-base region that is formed in the base region so as to be exposed from the connection hole and that has an impurity concentration higher than the base region;
wherein the connection electrode is electrically connected to the second in-base region in the connection hole.

12. The semiconductor device according to claim 11,
wherein the second in-base region is formed at a distance from the in-base region.

13. The semiconductor device according to claim 1,
wherein the trench gate structure includes a trench formed in the main surface, a gate insulating film covering a wall surface of the trench, a gate embedded electrode embedded in the trench with the gate insulating film between the gate embedded electrode and the trench, an electrode recess portion formed at an electrode surface of the gate embedded electrode, and a recess insulator covering the electrode recess portion,
the insulating film covers the gate embedded electrode, and has the connection hole that exposes the recess insulator, and
the connection electrode has a portion facing the gate embedded electrode across the recess insulator in the connection hole.

14. The semiconductor device according to claim 13,
wherein the in-base region is formed at a distance from the recess insulator.

15. The semiconductor device according to claim 13,
wherein the connection hole exposes the emitter region and the recess insulator.

16. The semiconductor device according to claim 13,
wherein the recess insulator has a portion that faces the base region along a surface direction of the main surface.

17. The semiconductor device according to claim 13,
wherein the recess insulator has an embedded portion placed closer to a side of a bottom wall of the trench than the main surface and a projection portion placed higher than the main surface in a cross-sectional view.

18. The semiconductor device according to claim 13,
wherein the insulating film has an insulating main surface placed higher than an upper end portion of the recess insulator.

19. The semiconductor device according to claim 1, further comprising:
a terminal electrode that is formed integrally with the connection electrode and that covers the insulating film.

20. The semiconductor device according to claim 1, further comprising:
a terminal electrode that is formed structurally independently of the connection electrode and that covers the insulating film and the connection electrode.
